(19) United States
(12) Patent Application Publication
(10) Pub. No.: US 2012/0169365 A1
(43) Pub. Date: Jul. 5, 2012

(54) SUBSTRATE INSPECTING APPARATUS AND ALIGNING METHOD IN SUBSTRATE INSPECTING APPARATUS

(75) Inventor: Haruo Iwatsu, Koshi-shi (JP)

(73) Assignee: Tokyo Electron Limited, Tokyo (JP)

(21) Appl. No.: 13/395,291

(22) PCT Filed: Sep. 9, 2010
(86) PCT No.: PCT/JP2010/065556

§ 371 Date: Mar. 9, 2012

(30) Foreign Application Priority Data
Sep. 11, 2009 (JP) 2009-211003

(51) Int. Cl. G01R 31/20; G01R 1/067

(52) U.S. Cl. 324/750.24; 324/755.01

(57) ABSTRACT

A substrate inspecting apparatus includes an inspecting apparatus main body for electrically inspecting a substrate on which an electronic circuit and electrode pads are formed, and a contactor electrically connected to the inspecting apparatus main body. The contactor includes contact portions made of conductive material. In the substrate inspecting apparatus, the contact portions are electrically connected to the electrode pads of the substrate via conductive liquid to inspect the electronic circuit formed on the substrate.

### FIELD OF THE INVENTION

The present invention relates to a substrate inspecting apparatus which performs electrical inspection for a substrate, and a substrate aligning method of the substrate inspecting apparatus.

### BACKGROUND OF THE INVENTION

With miniaturization, high speed and high integration of semiconductor devices, electrode pads which are arranged on substrates on which these semiconductor devices are formed, and are electrically connected to peripheral components of the substrates are also being miniaturized.

In a substrate inspecting apparatus for performing inspection for a substrate on which semiconductor devices are formed, such electrode pads are used to exchange signals between an inspecting apparatus main body of the substrate inspecting apparatus and the substrate. The substrate inspecting apparatus is provided between the substrate and the inspecting apparatus main body and has a contactor for electrically connecting the inspecting apparatus main body and the substrate. The contactor has contact portions to be electrically connected to electrode pads of the substrate. Since the electrode pads are being miniaturized as described above, the contact portions of the contactor are required to be more compact in addition to being miniaturized.

In such a conventional substrate inspecting apparatus, when the contact portions of the contactor contact the electrode pads, a load is applied thereto in both vertical and horizontal directions. This is to ensure that the contact portions penetrate through an insulating layer composed of, for example, an oxide film and formed on a surface of a wire terminal of a metal wire so that the contact portions can contact the electrode pads.

In this connection, there has been proposed a contactor structure where a wire pattern is formed on a base film made of, for example, resin, and a contact portion to be electrically connected to an electrode pad of a substrate is formed in a portion of the wire pattern (see, e.g., Japanese Patent Application Publication No. 2000-180469).

In addition, there has been proposed a contactor where conductive probe electrodes are arranged in a line or in a two-dimensional lattice shape on a surface of a circuit substrate on which a plurality of line patterns is formed and various arrangements can be employed to prevent circuit-short between electrode pads of the substrate under inspection (see, e.g., Japanese Patent Application Publication No. H07-63788).

However, the above described substrate inspecting apparatus has the following problems in alignment of the contactor with the substrate.

Reliable electrical connection between the electrode pad of the substrate and the contact portion of the contactor requires highly-precise alignment of the contactor with the substrate. A method has been typically used which performs alignment while observing alignment marks arranged on a substrate with a CCD camera provided in an inspecting apparatus.

However, with miniaturization and compactness of the electrode pads of the substrate and the contact portions of the contactor, reliable contact between the electrode pads of a semiconductor device on the substrate under inspection and the corresponding contact portions of the contactor requires highly-precise alignment. If such highly-precise alignment cannot be achieved, there is a probability that the electrode pad on the substrate is not electrically connected to the contact portion of the contactor, which may result in infeasibility of substrate inspection or wrong inspection results.

In the method of applying a load in both vertical and horizontal directions, with increase in the number of electrode pads in accordance with high integration, for example, if a load of 5 g per electrode pad is applied, a substrate on which 1000 semiconductor devices, each having 1000 wire terminals, are formed requires a total load of 5 tons (=5 g×1000×1000).

### SUMMARY OF THE INVENTION

In view of the above, the invention provides a substrate inspecting apparatus and an aligning method, in which a contactor can be aligned on a substrate with high precision even if electrode pads of the substrate and contact portions of the contactor becomes miniaturized and highly-compact, and reliable electrical connection between the electrode pads of the substrate and the corresponding contact portions of the contactor can be obtained without applying a large load.

In accordance with a first aspect of the present invention, there is provided a substrate inspecting apparatus including an inspecting apparatus main body for electrically inspecting a substrate on which an electronic circuit and electrode pads are formed; and a first contactor which includes contact portions made of conductive material and is electrically connected to the inspecting apparatus main body. In the substrate inspecting apparatus, the contact portions are electrically connected to the electrode pads of the substrate via conductive liquid.

In accordance with a second aspect of the present invention, there is provided an aligning method, in a substrate inspecting apparatus to electrically inspect a substrate on which an electronic circuit and electrode pads are formed, for aligning a contactor with the substrate, the contactor electrically connecting the substrate and an inspecting apparatus main body of the substrate inspecting apparatus. The aligning method includes: a first hydrophilizing step of hydrophilizing electrode pads formed on the top of the substrate; a first liquid supplying step of supplying liquid onto the substrate; a first mounting step of mounting the contactor on the substrate on which the liquid is supplied; and an aligning step of aligning the contactor with the substrate via the liquid.

### BRIEF DESCRIPTION OF THE DRAWINGS

FIG. 1 is a front view including a partially sectional view, which shows a substrate inspecting apparatus according to a first embodiment of the present invention.

FIG. 2 is a block diagram showing an electric circuit of the substrate inspecting apparatus according to the first embodiment.

FIG. 3 is a block diagram showing an electric circuit of the substrate inspecting apparatus according to the first embodiment.

FIG. 4 is a schematic sectional view showing one example of a contactor wafer according to the first embodiment.

FIG. 5 is a schematic sectional view showing another example of the contactor wafer according to the first embodiment.

FIG. 6 is a schematic sectional view showing a further example of the contactor wafer according to the first embodiment.

FIG. 7 is a schematic sectional view showing a still further example of the contactor wafer according to the first embodiment.

FIG. 8 is a flow chart showing various processes of an aligning method of the substrate inspecting apparatus according to the first embodiment.

FIGS. 9A to 9F are schematic sectional views of a contactor and a substrate in steps of an aligning method in the substrate inspecting apparatus according to the first embodiment.

FIGS. 10A and 10B are schematic sectional views of the contactor and the substrate in steps of an aligning method in the substrate inspecting apparatus according to the first embodiment.

FIG. 11 is a flow chart for explaining processes of a method for manufacturing a contactor wafer according to the first embodiment.

FIGS. 12A to 12F are schematic sectional and plan views showing the contactor wafer in steps of the method for manufacturing the contactor wafer according to the first embodiment.

FIGS. 13A to 13F are schematic sectional and plan views showing the contactor wafer in steps of the method for manufacturing the contactor wafer according to the first embodiment.

FIG. 14 is a front view including a partially sectional view, which shows a substrate inspecting apparatus according to a second embodiment of the present invention.

FIG. 15 is a block diagram showing an electric circuit of the substrate inspecting apparatus according to the second embodiment.

FIG. 16 is a front view including a partially sectional view, which shows a substrate inspecting apparatus according to a modification of the second embodiment.

FIG. 17 is a block diagram showing an electric circuit of the substrate inspecting apparatus according to the modification of the second embodiment.

FIG. 18 is a front view including a partially sectional view, which shows a substrate inspecting apparatus according to a third embodiment of the present invention.

FIG. 19 is a block diagram showing an electric circuit of the substrate inspecting apparatus according to the third embodiment.

FIGS. 20A and 20B show a flow chart for explaining processes of an aligning method in the substrate inspecting apparatus according to the third embodiment.

FIGS. 21A to 21L are schematic sectional views of a contactor and a substrate in steps of an aligning method in the substrate inspecting apparatus according to the third embodiment.

FIG. 22 is a front view including a partially sectional view, which shows a substrate inspecting apparatus according to a fourth embodiment of the present invention.

FIGS. 23A to 23F are schematic sectional and plan views showing a contactor wafer in steps of a method for manufacturing the contactor wafer according to the fourth embodiment.

### DETAILED DESCRIPTION OF THE EMBODIMENTS

In accordance with embodiments of the present invention, it is possible to align a contactor on a substrate with high precision even if electrode pads of the substrate and contact portions of the contactor become miniaturized and highly-compact, and ensure electrical connection between the electrode pads of the substrate and the contact portions of the contactor without applying a large load.

Hereinafter, embodiments of the present invention will be described with reference to the accompanying drawings.

### First Embodiment

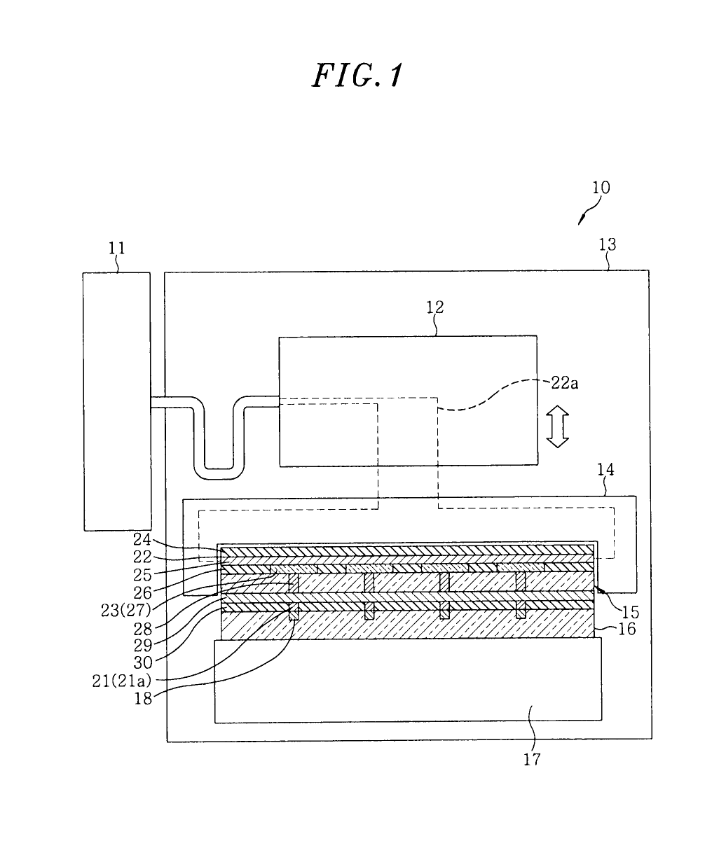

First, a substrate inspecting apparatus, a contactor wafer, an aligning method of the substrate inspecting apparatus and a method for manufacturing the contactor wafer according to a first embodiment will be described with reference to FIGS. 1 to 12.

As shown in FIG. 1, a substrate inspecting apparatus 10 includes a tester main body 11, a test head 12 and an auto-prober 13.

The tester main body 11 includes an electric circuit, such as an LSI (Large Scale Integrated Circuit), which generates signals for testing electronic circuits and so on in a plurality of semiconductor chips formed on a substrate (wafer) and reads signals from the electronic circuits and so on.

The test head 12 is vertically movable and is disposed within the auto-prober 13. The test head 12 has a contactor holder 14 and a contactor 15. The contactor 15 is provided between the tester main body 11 and a substrate (hereinafter referred to as “wafer”) 16 to be inspected. The contactor 15 sends signals from the tester main body 11 to the wafer and vice versa. The contactor holder 14 is provided between the test head 12 and the contactor 15 and holds the contactor 15 at the test head 12. Specifically, the contactor holder 14 is provided below the test head 12 and the contactor 15 is held by the lower part of the contactor holder 14.

The auto-prober 13 has a chuck 17 for attracting and holding the wafer 16. The auto-prober 13 and the chuck 17 have a temperature adjustment mechanism (not shown) or the like for adjusting temperature of the wafer 16 to a predetermined temperature. Electrode pads 18 are formed on the wafer 16.

As shown in FIG. 1, in this embodiment, the contactor 15 is composed of a semiconductor wafer. Accordingly, in this embodiment, the contactor 15 is referred to as a “contactor wafer.” Different embodiments, the contactor 15 may be composed of other materials than the semiconductor wafer.

Lead wires 21 each having a contact portion 21a formed thereon, contact points 22 and a test circuit 23 are formed on the contactor wafer 15 (the contact portions 21a being not shown and the lead wires 21 and the contact portions 21a being integrally shown in FIG. 1). When the contact portions 21a formed on the lead wires 21 contact the electrode pads 18 of the wafer 16, the contactor wafer 15 and the wafer 16 are electrically interconnected. In this embodiment, the lead wires 21 each having the contact portion 21a formed thereon are provided on the lower side of the contactor wafer 15 (facing the wafer 16). The lead wire and the contact portion 21a are made of conductive material such as metal or the like.

The contact points 22 are provide on the side of the contactor holder 14 of the contactor wafer 15 and electrically interconnect the contactor wafer 15 and the contactor holder 14. The contact points 22 may be provided on the upper side of the contactor wafer 15. Alternatively, as schematically shown in FIG. 1, the contact points 22 may be provided in a lateral side of the contactor wafer 15. The contact points are also made of conductive material such as metal or the like.

The test circuit 23 is provided within the contactor wafer 15 between the lead wires 21 and the contact points 22. The test circuit 23 may be formed by a process using a semiconductor manufacturing technology (semiconductor process).

Wires 22a electrically interconnecting the contact points 22 of the contactor wafer 15 and the tester main body 11 are provided within the contactor holder 14 and the test header 12. That is, the contactor wafer 15 is provided between the tester main body 11 and the wafer 16 and sends signals from the tester main body 11 to the wafer 16 via the wires 22a and vice versa.

In addition to the electrode pads 18, a dummy electrode pad having no electrical wiring may be formed on the wafer 16 and a dummy contact portion contacting the dummy electrode pad may be formed on the contactor wafer 15. The dummy contact portion is formed on, for example, the circumference of the contact wafer 15 and is not electrically connected to the test circuit 23.

As shown in FIG. 1, the contactor wafer 15 includes an insulating layer 24, a wire 25 connected to the contact points 22, the test circuit 23 and a pad 27 which are separated from each other by an insulating layer 26, through electrodes 28 formed in a wafer base, a wire 29, an insulating layer 30, and the contact portions 21a separated by the insulating layer 30 in order from the top.

In this embodiment, the tester main body 11 acts as an inspecting apparatus main body. In this embodiment, the test head 12 and the contactor holder 14 act as a fixing mechanism.

The test head 12 may be provided either inside or outside the auto-prober 13.

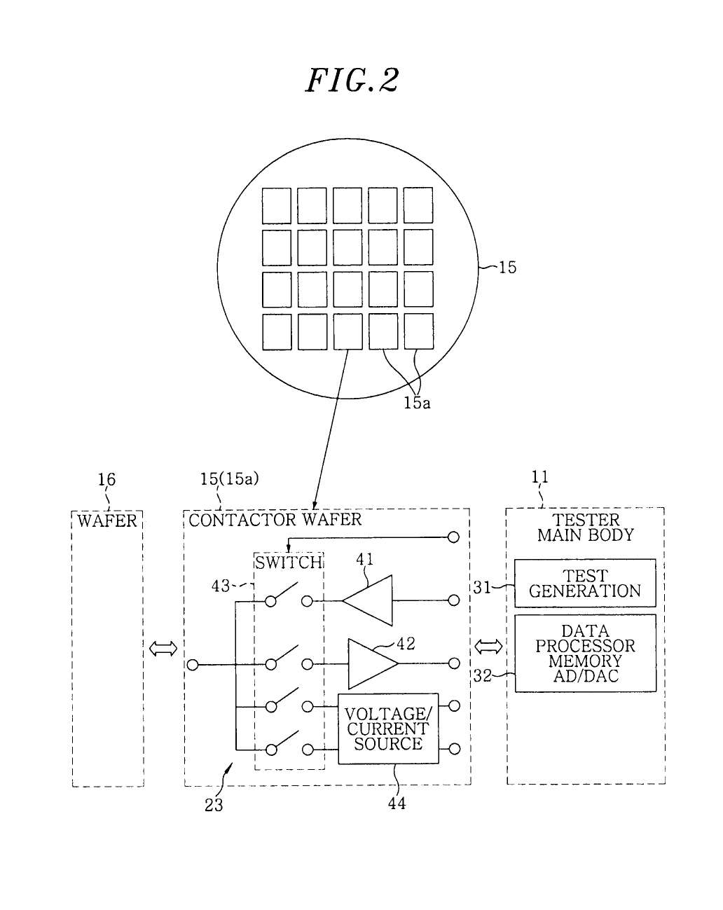

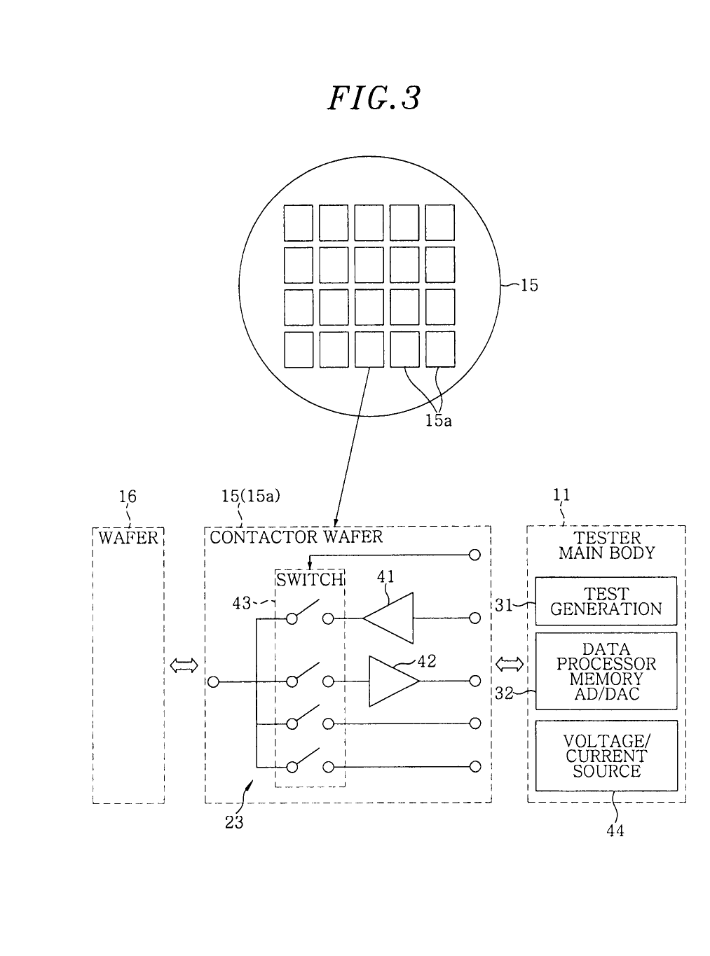

Next, an electrical circuit configured to inspect a substrate by using the substrate inspecting apparatus according to this embodiment will be described with reference to FIGS. 2 and 3.

As shown in FIG. 2, when a substrate is inspected by using the substrate inspecting apparatus, an electrical circuit is configured by the tester main body 11, the contactor wafer 15 and the wafer 16. The tester main body 11 includes a test generation 31 and a data processor 32. The data processor 32 includes a memory and an analog-digital/digital-analog converter (AD/DAC) in addition to a data processor. The contactor wafer 15 includes a plurality of test circuit parts 15a, as shown in a plane view of the contactor wafer 15 arranged in the upper side of a block diagram of FIG. 2. Each test circuit part 15a includes a contact pads (contact portions) 21a and a test circuit 23. The test circuit 23 of each test circuit part 15a includes a driver 41, a comparator 42 and a switch 43.

For example, as specifications, frequency bands of the driver 41, the comparator 42 and the switch 43 may be about 200 MHz to about 10 GHz, the driver 41 may operate under conditions of Vol/Voh fixed (worst condition)/variable (which may not be programmable), and the comparator 42 may operate under conditions of Vil/Vih fixed (worst condition)/variable (which may not be programmable). The switch 43 may be composed of five MOSFETs (Metal Oxide Semiconductor Field Effect Transistors). In this case, among these, four MOSFETs may be used for DC measurement and one MOSFET may be used for fast measurement.

A voltage/current source 44 may be included in the test main body 11, not in the test circuit parts 15a of the contactor wafer 15. An example where the voltage/current source 44 is included in the tester main body 11 is shown in FIG. 3. In the example shown in FIG. 3, since the voltage/current source 44 is included in the tester main body 11, no voltage/current source may be included in the test circuit parts 15a of the contactor wafer 15.

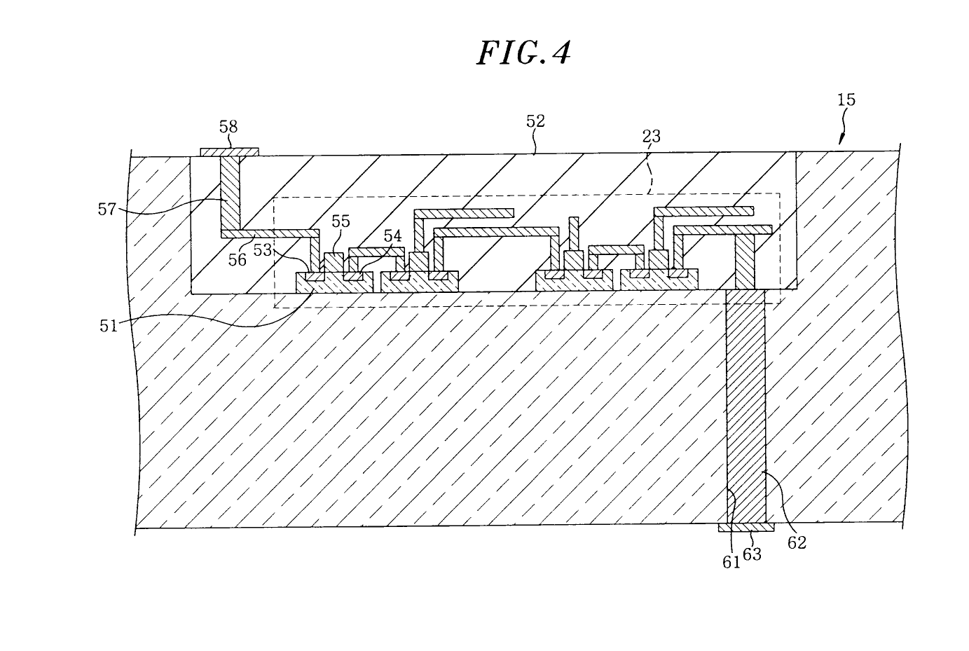

Next, a test circuit of the contactor wafer will be described with reference to FIGS. 4 to 7.

In an example shown in FIG. 4, a test circuit 23 is formed within the contactor wafer 15 according to a semiconductor process. As shown in FIG. 4, in the upper side of the contactor wafer 15, there are formed semiconductor devices 51 composed of, for example, MOSFETs or the like, a switch, a driver and a comparator according to a semiconductor process. The semiconductor devices 51 formed in the upper side of the contactor wafer 15 are coated by an insulating layer 52. Electrode terminals of each semiconductor device 51 (electrode terminals corresponding to a source 53, a drain 54 and a gate 55 if each semiconductor 51 is a MOSFET) are electrically connected to a corresponding pad formed on the insulating layer 2 via a wire 56, a via electrode 57 and so on. In the meantime, a through hole 61 penetrating through the contactor wafer 15 from top to bottom is formed in a portion of the contactor wafer 15 and an electrode terminal of a portion of a semiconductor device 51 formed in the upper side of the contactor wafer 15 is electrically connected to a corresponding pad 63 formed in the bottom of the wafer 15 via the through electrode 62 formed in the through hole 61.

In an example shown in FIG. 5, the test circuit 23 is formed in a wafer 15b different from the contactor wafer 15 according to a semiconductor processor and the wafer 15b in which the test circuit 23 is formed is buried in a concave portion of the contactor wafer 15. In this case, in the wafer 15b buried in the contactor wafer 15, an electrode terminal of a portion of a semiconductor device 51 is electrically connected to a corresponding pad 58 formed in the top of the wafer 15b via a wire 56, a via electrode 57 and so on, like FIG. 4. In addition, an electrode terminal of a portion of a semiconductor device 51 is electrically connected to a pad 63 formed in the bottom of the contactor wafer 15 via a through electrode 62a formed in a through hole 61a penetrating through the wafer 15b from top to bottom, a pad 63a formed in the bottom of the concave portion of the contactor wafer 15, and a through electrode 62 formed in a through hole 61 extending from the bottom of the concave portion of the contactor wafer 15 to the bottom of the contactor wafer 15.

In an example shown in FIG. 6, a test circuit 23 is formed in a wafer 15c different from the contactor wafer 15 according to a semiconductor processor and the wafer 15c in which the test circuit 23 is formed is mounted on the contactor wafer 15, like FIG. 5. In the mounted wafer 15c, an electrode terminal of a portion of a semiconductor device is electrically connected to a corresponding pad 58 formed in the top of an insulating layer 52 of the wafer 15c via a wire 56 and a via electrode 57 formed in the insulating layer 52, like FIGS. 4 and 5. In addition, an electrode terminal of a portion of a semiconductor device 51 is electrically connected to a pad 63 formed in the bottom of the contactor wafer 15 via a through electrode 62b formed in a through hole 61b penetrating through the wafer 15c from top to bottom, a pad 63b formed in the bottom of the contactor wafer 15, and a through electrode 62 formed in a through hole 61 extending through the contactor wafer 15 from the top to the bottom.

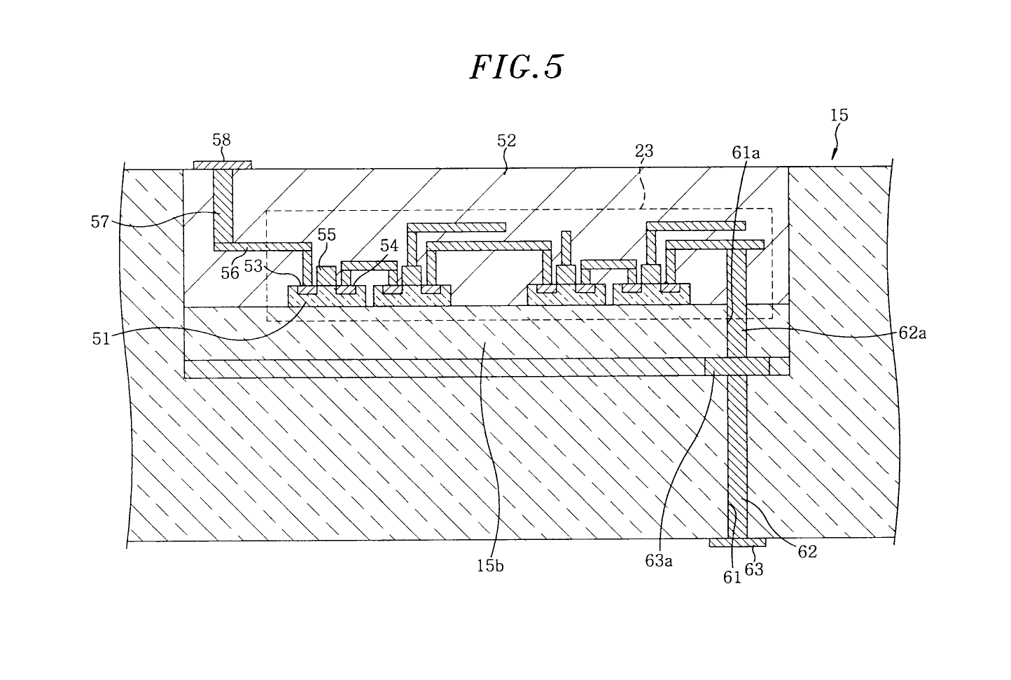

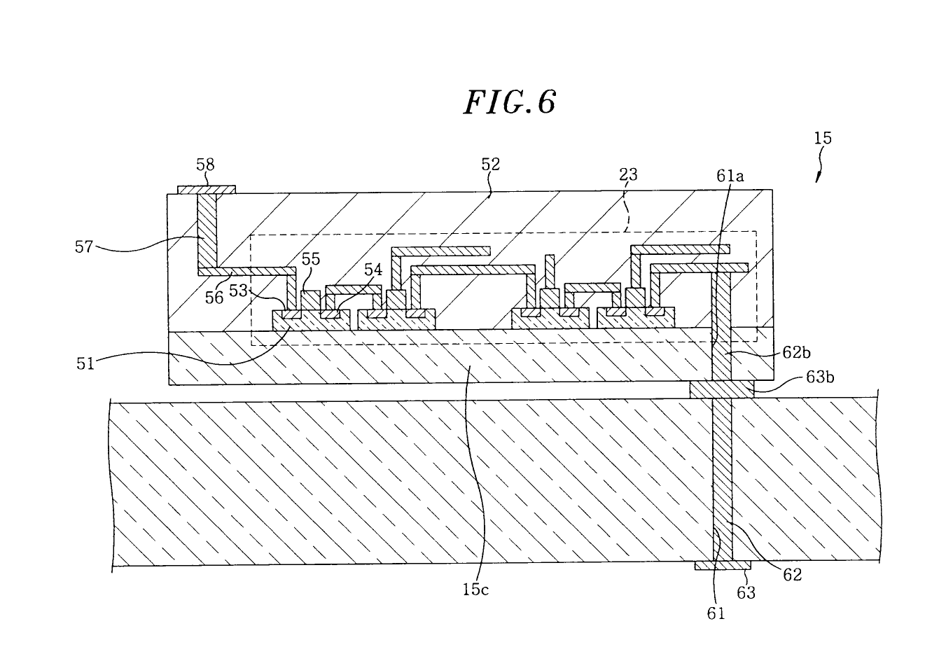

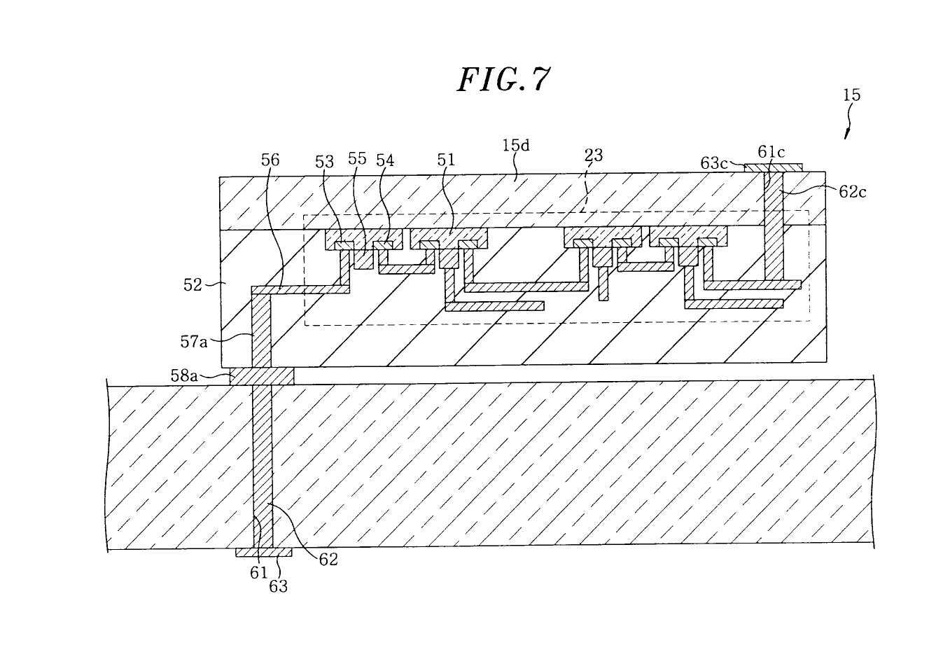

In an example shown in FIG. 7, a test circuit 23 is formed in a wafer 15d different from the contactor wafer 15 according to a semiconductor processor and the wafer 15d in which the test circuit 23 is formed is mounted on the contactor wafer 15 in such a manner that an insulating layer 52 on the wafer 15d faces the contactor wafer 15, like FIG. 6. In the mounted wafer 15d, an electrode terminal of a portion of a semiconductor device 51 is electrically connected to a pad 63c formed in the back side (top) of the wafer 15d via a through electrode 62c formed in a through hole 61c penetrating through the wafer 15d from one side to another side. In addition, an electrode terminal of a portion of a semiconductor device 51 is electrically connected to a pad 58a formed in the top of the contactor wafer 15 via a wire 56 formed in the insulating layer 52 and a via electrode 57a formed in the insulating layer 52.

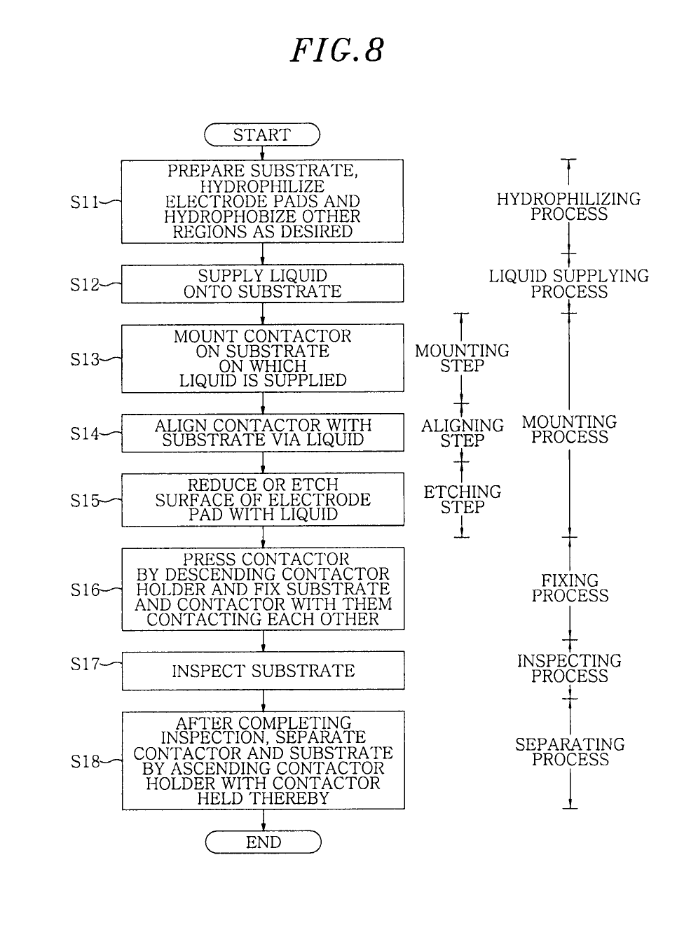

Next, an aligning method for aligning a contactor and a substrate in the substrate inspecting apparatus of this embodiment will be described with reference to FIGS. 8 to 10. The aligning method in this embodiment includes a substrate inspecting method according to an embodiment of the present invention.

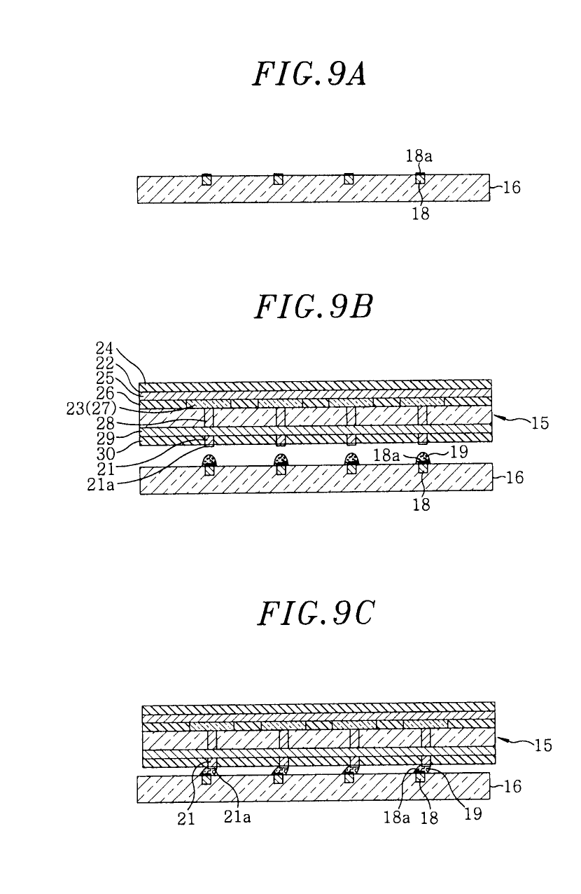

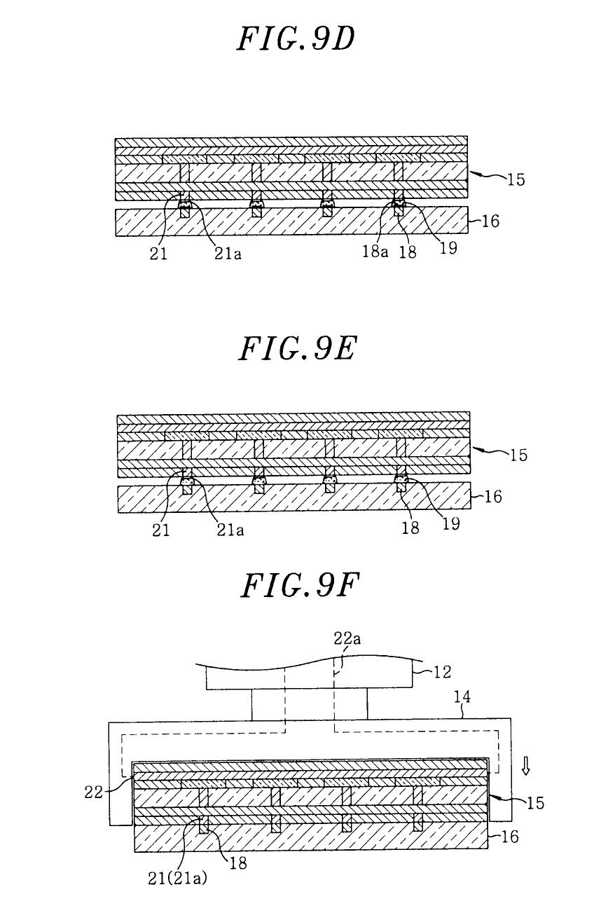

In the aligning method (substrate inspecting method) in the substrate inspecting apparatus of this embodiment, first, a wafer 16 is prepared and is subjected to a hydrophilizing process for hydrophilizing a surface of an electrode pad 18 of the wafer 16 (S11 in FIG. 8). FIG. 9A is a schematic sectional view of the wafer 16 subjected to the process of S11. In FIGS. 9A to 9D, the surface of the electrode pad 18 subjected to the hydrophilizing process is denoted by reference numeral 18a.

The hydrophilizing process may be performed by, for example, applying a photocatalyst on the surface and then selectively irradiating the surface with a UV ray via a mask. If the above-mentioned dummy electrode pad is present, the hydrophilizing process may be also performed on the dummy electrode pad. In this embodiment, a hydrophobizing process is performed on regions other than the electrode pad 18. The hydrophobizing process may be performed by, for example, selectively applying hydrophobic material such as an organic silicon compound. In different embodiments, the hydrophobizing process may not be performed.

Next, a liquid supplying process is performed on the wafer 16 with the hydrophilized surface 18a of the electrode pad 18 and the other hydrophobized regions (S12).

Specifically, a liquid is supplied on and around the hydrophilized surface 18a of the electrode pad 18. This liquid may be supplied by using, for example, various methods such as application, spraying, discharging and so on. By the supply of the liquid, liquid droplets 19 are formed on and around the hydrophilized surface 18a of the electrode pad 18, as shown in FIG. 9B.

The liquid may not be directly supplied to the hydrophilized surface 18a of the electrode pad 18. Even when the liquid is thinly applied on the entire surface of the wafer 16, since the liquid moves from the hydrophobized regions to the hydrophilized surface 18a, the liquid droplets 19 are formed on and around the hydrophilized surface 18a, as shown in FIG. 9B. In addition, the liquid droplets 19 may be formed by selectively applying the liquid on the electrode pad 18 by using an inkjet printing technique.

In this embodiment, the supplied liquid (liquid droplets 19) preferably has a conductivity. In addition, for example if the electrode pad 18 is hydrophilized and other regions are hydrophobized, the liquid is preferably hydrophilic liquid, for example, water-containing liquid. If the electrode pad 18 is hydrophobized and other regions are hydrophilized, the liquid may be hydrophobic (lipophilic) liquid.

If the above-mentioned dummy electrode pad is present, liquid may be also applied on the dummy electrode pad.

Next, a mounting process is performed. In this embodiment, the mounting process includes a mounting step (S13) of mounting a contactor wafer 15 on the wafer 16, an aligning step (S14) of aligning the contactor wafer 15 with the wafer 16, and an etching step (S15) of cleaning the electrode pad 18 of the wafer 16 and a contact portion 21a of the contactor wafer 15.

In the mounting step, as shown in FIG. 9C, the contactor wafer 15 is mounted on the wafer 16 in which the liquid droplets 19 are supplied on the surface 18a of the electrode pad 18. Specifically, alignment is first performed by an aligning mechanism or the like equipped in the substrate inspecting apparatus such that the electrode pads 18 face the respective contact portions 21a formed on the lead wires 21 of the contactor wafer 15. This alignment does not require high precision. Next, with the liquid droplets 19 formed on and around the hydrophilized surfaces 18a of the electrode pads 18, the contactor wafer 15 is mounted on the wafer 16. When mounted, there is no need to apply a transverse (horizontal) force to the contactor wafer 15.

The hydrophilizing process may be performed on the contact portions 21a of the mounted contactor wafer 15, like the electrode pads 18 of the wafer 16. Alternatively, the contact portion 21a may be formed by using hydrophilic material such as metal or the like having wettability to liquid.

In addition, the contactor wafer 15 may be mounted on the wafer 16 by means of a transfer apparatus (not shown) provided separately from the test head 12 integrated with the contactor holder 14. In addition, the contactor wafer 15 may be mounted on the wafer 16 by separating and dropping the contactor wafer 155 held by the contactor holder 14 of the test head 12 from the contactor holder 14 onto the wafer 16.

The contactor wafer 15 mounted on the wafer 16 is self-aligned with the wafer 15 in the aligning step, as shown in FIG. 9D (S14). This self-alignment can be achieved because the contactor wafer 15 can move to be aligned with the wafer 16 as the liquid droplets 19 move to contact the hydrophilic surfaces 18a of the electrode pads 18 of the wafer 16 and the corresponding contact portions 21a of the contactor wafer 15 and because the liquid droplets 15 stay between the surfaces 18a and the corresponding contact portions 21a by virtue of a surface tension without being widened. Accordingly, it is more preferable that hydrophilic liquid is used and the electrode pads 18 and the contact portions 21a are hydrophilized in terms of a surface tension.

If the above-mentioned dummy electrode pad is provided in the wafer 16 and the above-mentioned dummy contact portion is provided in the contactor wafer 15, the dummy electrode pad and the dummy contact portion contact and are aligned with each other via the liquid.

After the contactor wafer 15 and the wafer 16 are aligned with each other in this manner, the contactor wafer 15 and the wafer 16 are left for a predetermined period of time, as shown in 9E. In the meantime, the surfaces of the electrode pads 18 and/or the contact portions 21a are reduced or etched by the liquid droplets 19 (S15). That is, even when an oxide film or a film generated due to contamination is formed on the surfaces of the electrode pads 18 and/or the contact portions 21a, the oxide film or the generated film is reduced or etched out by the liquid droplets 19.

For such reduction or etching, the liquid (liquid droplets 19) uses a property to reduce or etch the oxide film or the like. Such reduction or etching can improve electrical contact between the electrode pad 18 and the contact portion 21a.

Next, as shown in FIG. 9F, the contactor wafer 15 is pressed to the wafer 16 by descending the contactor holder 14 and a fixing process to fix the contactor wafer 15 and the wafer 16 is performed with them contacting each other (S16). In FIG. 9F, the contact portion 21a is not shown and the lead wire 21 and the contact portion 21a are integrally shown. This may be true of the following figures. Since the electrode pads 18 and the contact portions 21a have been already aligned with each other in the aligning process (S14), a downward force may be only applied in the fixing process (S16). In addition, since the oxide film or the like has been removed from the surfaces of the electrode pads 18 in the etching process (S15), there is no need to apply a horizontal force to the contactor wafer 15.

In the fixing process, the contact points 22 of the contactor wafer 15 are electrically connected to respective contact points of the contactor holder 14. Accordingly, a (electronic) circuit to be inspected, which is formed in the wafer 16, is connected to the tester main body 11 via the contact portions 21a formed in the contactor wafer 15, the test circuit 23, the contact points 22, and the wires 22a formed in the contactor holder 14.

After the aligning method (S11 to S16) is performed in the substrate inspecting apparatus as described above, an inspecting process to inspect the circuit of the wafer 16 connected to the tester main body 11 is performed (S17). In this embodiment, based on a signal sent from the tester main body 11, a signal is generated by controlling a switch and a driver of the test circuit 23 provided in the contactor wafer 15 and is inputted to an input electrode pad 18 of the circuit of the wafer 16. As a result, an output signal is generated in the circuit under inspection. This output signal is outputted from an output electrode pad 18 of the wafer 16, is read by controlling a switch and a comparator of the test circuit 23 of the contactor wafer 15, and is sent to the tester main body 11. It is determined in the test main body 11 whether or not the circuit under inspection of the wafer 16 is normally operated.

In this embodiment, the generation and reading of signal for inspection are performed in the contactor wafer 15 adjacent to the wafer 16. This may result in reduced wire length from the wafer 16 to a signal reading circuit. A long circuit wire may greatly increase a parasitic capacitance of the circuit wire and, particularly, make it difficult to detect a high frequency signal with high precision. Accordingly, in this embodiment, for inspection of a semiconductor substrate having a circuit operating with a high frequency of, particularly, 1 GHz or more, it is possible to inspect the substrate with higher precision than conventional substrate inspecting apparatuses.

After the inspecting process, a separating process is performed (S18). In the separating process, after the inspection is completed, the contactor holder 14 is ascended with the contactor wafer 15 held thereby and the contactor wafer 15 and the wafer 16 are separated from each other.

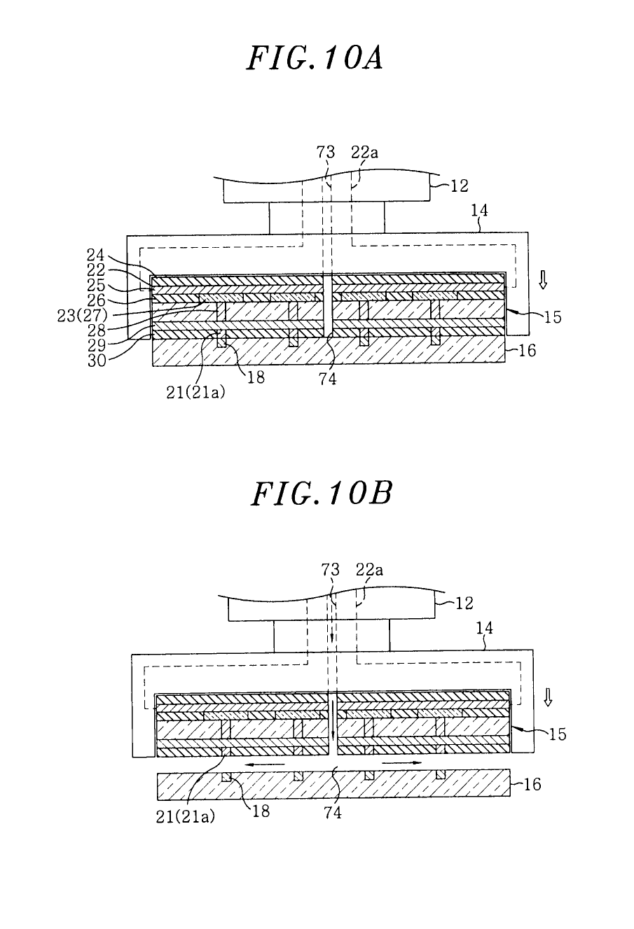

However, in some cases, the contactor wafer 15 and the wafer 16 aligned with each other through the liquid droplets 19 may not be separated from each other if the liquid droplets 19 are evaporated. In such cases, the contactor wafer 15 and the wafer 16 may be separated from each other by applying a pressure between the contactor wafer 15 and the wafer 16. FIGS. 10A and 10B show the contactor holder 14, the contactor wafer 15, the wafer 16 and so on before and after the separating process using the pressure application. As shown, when gas is sent to a through hole 74 provided in the contactor wafer 15 via a gas supplying pipe 73 provided in the test head 12 and the contactor holder 14, the contactor wafer 15 and the wafer 16 can be separated from each other. The through hole 74 may be provided in the center of the contactor wafer 15 or in a peripheral portion of the contactor wafer 1 where the contact portion 21a is not provided.

Alternatively, without the through hole 74 provided in the contactor wafer 15, gas may be blown between the contactor wafer 15 and the wafer 16 from a peripheral portion of the wafer 16. In addition, the contactor wafer 15 and the wafer 16 may be separated from each other by depressing an atmosphere without requiring a high pressure. In addition, the contactor wafer 15 and the wafer 16 may be separated from each other by selecting and using liquid whose adhesion is weakened with being dried, without using a special method. Alternatively, the contactor wafer 15 and the wafer 16 may be separated from each other by introducing liquid between the contactor wafer 15 and the wafer 16. In addition, while being mounted on the wafer 16, the contactor wafer 15 may be moved to a separation process chamber where the contactor wafer 15 is separated from the wafer 16.

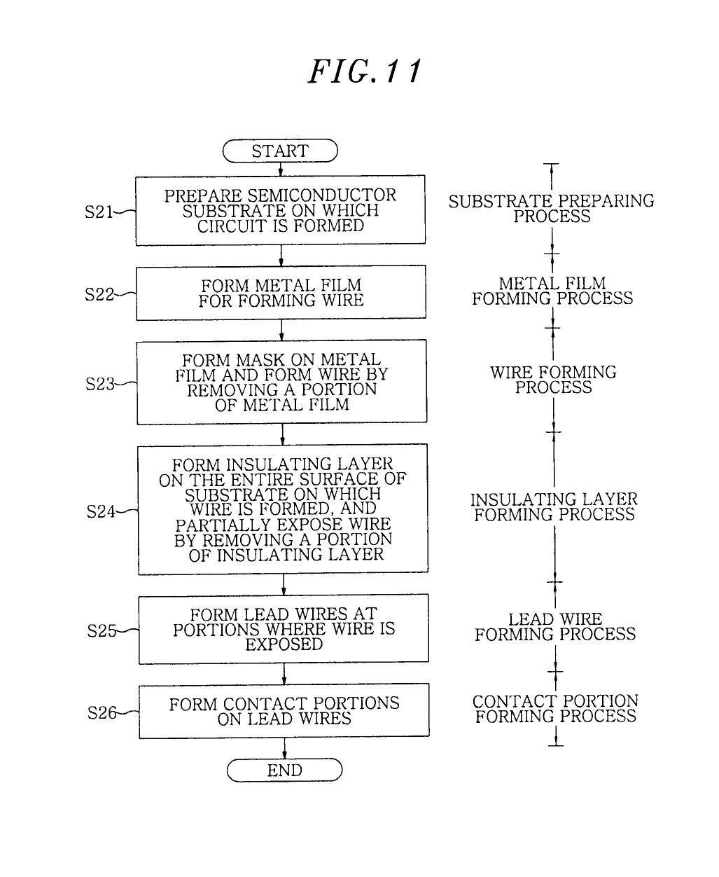

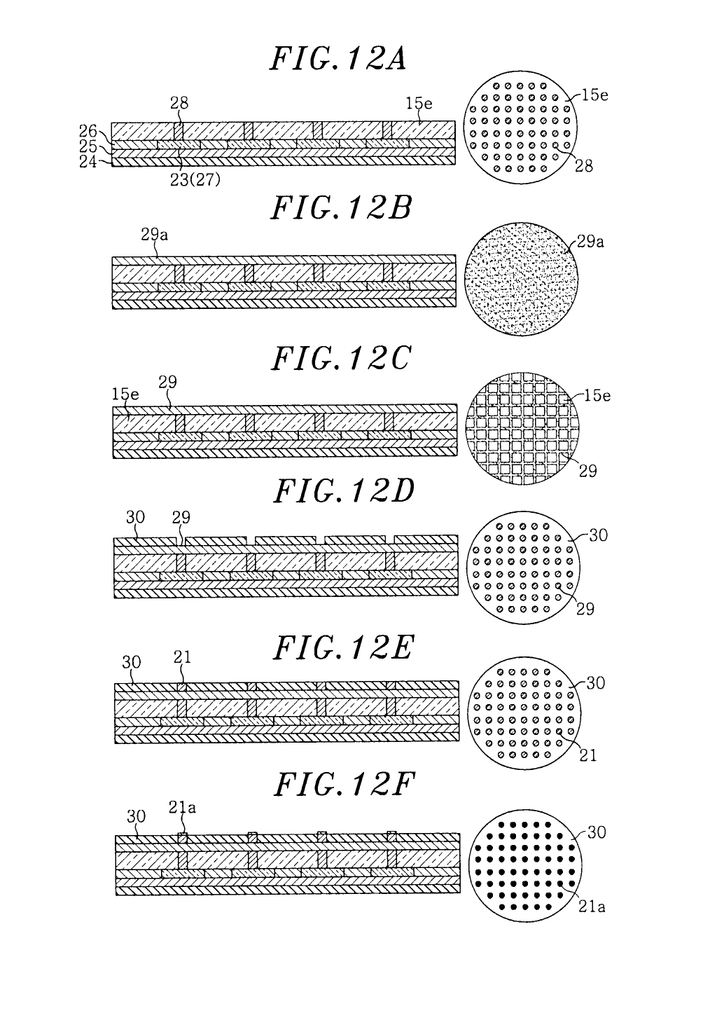

Next, a method for manufacturing the contactor wafer according to this embodiment will be described with reference to FIGS. 11 and 12.

FIG. 11 is a flow chart for explaining processes of a method for manufacturing a contactor wafer according to this embodiment. FIG. 12 is schematic sectional and plan views showing a structure of a contactor wafer in steps of a method for manufacturing the contactor wafer according to this embodiment. FIGS. 12A to 12F show a structure of a contactor wafer after steps S21 to S26 in FIG. 11 are performed. The sectional view and the plane view are shown in the left and right sides in FIG. 12, respectively.

First, a substrate preparing step is performed (S21). Specifically, as shown in FIG. 12A, a wafer 15e having a predetermined circuit formed thereon by a semiconductor manufacturing technique including photolithography, film formation and so on is first prepared. Next, a test circuit 23 and a pad 27, which are separately formed in an insulating layer 26, a wire 25, and an insulating layer 24 are formed on the bottom of the wafer 15e. The test circuit 23 includes a driver, a comparator and a switch. The wafer 15e has through electrodes 28 which electrically connect the test circuit 23 and a wire 29 which will be described later.

Next, as shown an FIG. 12B, a metal film 29a for forming the wire 29 is formed on the wafer 15e (metal film forming step: S22).

Subsequently, a mask is formed on the metal film 29a and the wire 29 is formed by etching the metal film 29a exposed from the mask, as shown in 12C (wire forming step: S23). The etching may be either wet etching or dry etching. The wire 29 is formed to extend to the periphery of the wafer 15e. The wire 29 extending to the periphery is used to exchange signals with the inspecting apparatus.

Next, an insulating layer 30 is formed on a surface of the wafer 15e on which the wire 29 is formed, and openings are formed by photolithography and etching, as shown in FIG. 12D. The wire 29 is exposed in the openings. Alternatively, a mask may be formed at a position at which the openings are to be formed, the insulating layer 30 may be formed to cover the mask, the wire 29 and the top surface of the wafer 15e, and the openings may be formed in the insulating layer 30 by lifting off the mask. The insulating layer 30 may be formed using any methods including CVD, PVD, application, deposition and the like as long as they do not damage the wire previously formed. The insulating layer 30 may be made of any resin material such as polyimide in addition to a silicon oxide.

Next, by filling the openings of the insulating layer 30 with metal by using a plating or the like, lead wires 21 to be electrically connected with the wire 29 are formed as shown in FIG. 12E (lead wire forming step: S25).

Next, contact portions 21a are formed on the lead wires 21, as shown in FIG. 12F (contact portion forming step: S26). The contact portions 21a may have either a convex shape projecting from the top of the insulating layer 30 or a planar shape flush with the top of the insulating layer 30. Alternatively, the contact portions 21a may have a concave shape lower than the surface of the wafer 15e. In this case, the contact portions 21a may be electrically connected with the electrode pads 18 of the wafer 16 to be inspected via conductive liquid. A contactor wafer 15 is manufactured by the above-described manufacturing method.

In different embodiments, without performing the contact portion forming step S26, the wires 21 formed in the lead wire forming step S25 may be used instead of the contact portions 21a. In this case, the lead wires 21 may be formed to project from the top of the insulating layer 30.

In addition, surfaces of the contact portions 21a may be subjected to a hydrophilizing process. The hydrophilizing process may be performed by using the same method as the hydrophilizing process for the electrode pads 18 of the wafer 16 which has been described with reference to FIG. 9A. That is, the hydrophilizing process may be performed by applying a photocatalyst on the surfaces and then selectively irradiating the surfaces with a UV ray via a mask. Regions other than the contact portions 21a of the contactor wafer 15 may be subjected to a hydrophobizing process. In this case, the hydrophobizing process may be performed by selectively applying hydrophobic material such as an organic silicon compound.

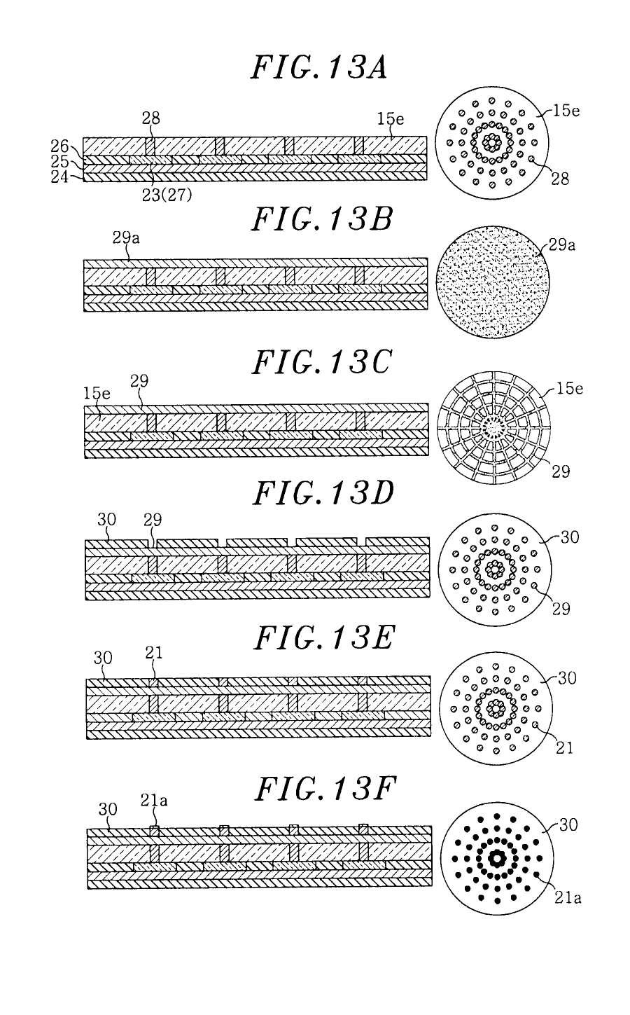

In the plan views shown in the right sides of FIGS. 12A to 12F, the wire 29 is made in a lattice shape and the lead wires 21 and the contact portions 21a are also arranged in a lattice shape. Alternatively, instead of the lattice shape, the wire 29, the lead wires 21 and the contact portions 21a may extend radially from the center of the wafer 16, for example as shown in FIGS. 13A to 13F. The example shown in FIGS. 13A to 13F is different in arrangement of the lead wires 21 and the contact portions 21a from and has substantially the same section as the example shown in FIGS. 12A to 12F. In FIGS. 13A to 13F, the same elements as those in FIGS. 12A to 12F are denoted by the same reference numerals and redundant description thereof will be omitted.

The contactor wafer may be designed to be in general use and contact portions unused may be electrically isolated in accordance with arrangement of electrode pads of the wafer. Electrical isolation of the contact portions unused may be performed before shipping of the contactor wafer or immediately before inspection after shipping of the contactor wafer. An Example of the method of performing the electrical isolation immediately before inspection may include a method of electrical isolation and conductivity recovery using an electrical isolation unit (e.g., a resist coating unit) and a conductivity recovery (restoration) unit (e.g., a resist peeling/developing unit), which are provided within or near the substrate inspecting apparatus. In this case, in response to an instruction from a host computer in a factory, electrical isolation may be performed within or near the substrate inspecting apparatus before inspection.

In the contactor wafer subjected to the insulating process, surfaces of unused ones of the formed contact portions are coated with insulating material. The insulating material may be, for example, a resist and may be applied using an inkjet printing method.

Alternatively, wires electrically connecting the unused ones of the formed contact portions may be cut by using, for example, a laser or the like.

As described above, even if electrode pads of a wafer to be inspected and contact portions of a contactor wafer becomes miniaturized and highly-compact, the substrate inspecting apparatus of this embodiment is capable of aligning the contactor wafer on the wafer with high precision and ensuring electrical connection between the electrode pads of the wafer and the contact portions of the contactor wafer without applying a large load.

### Second Embodiment

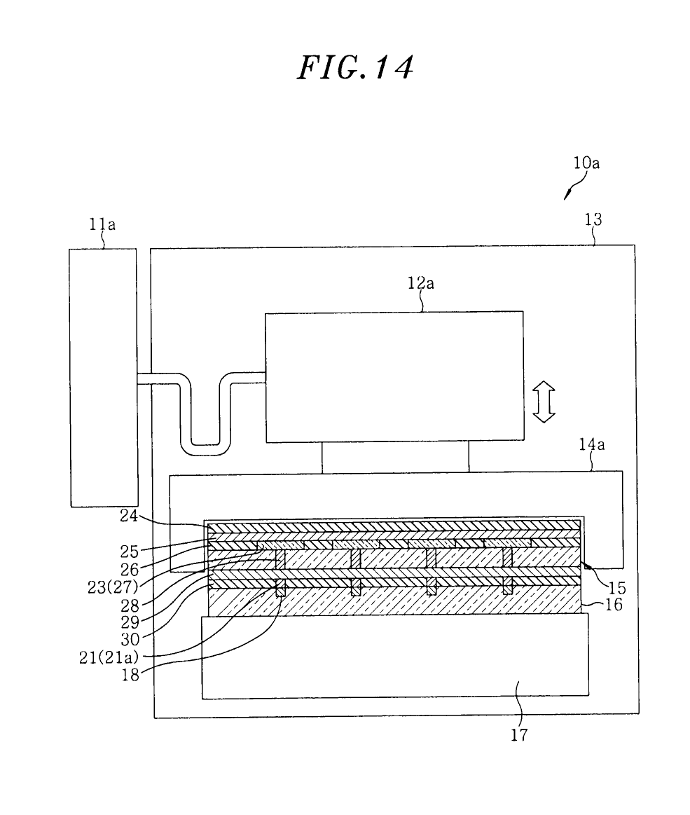

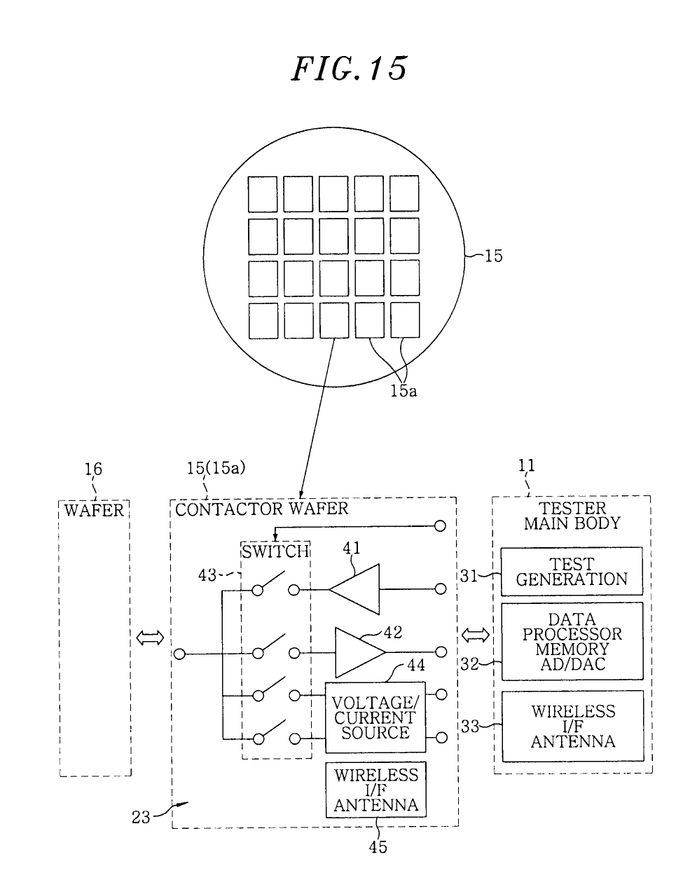

Next, a substrate inspecting apparatus and a contactor wafer according to a second embodiment will be described with reference to FIGS. 14 and 15. In the following description, the same elements described earlier are denoted by the same reference numerals and redundant despeription thereof will be omitted (this is true of subsequent modifications and embodiments).

A substrate inspecting apparatus 10a of this embodiment includes a tester main body 11a, a test head 12a and an auto-prober 13. The tester main body 11a includes an LSI (Large Scale Integrated Circuit) or the like with a circuit for generating test signals for testing a circuit of a wafer 16 to be inspected and a circuit for reading signals from the circuit under inspection of the wafer 16. The test head 12a is vertically movably disposed within the auto-prober 13 and has a contactor holder 14a and a contactor wafer 15. The contactor holder 14a is provided below the test head 12a and holds the contactor wafer 15 by the bottom of the contactor holder 14a. The auto-prober 13 has a chuck 17 for attracting and holding the wafer 16.

In this embodiment, the tester main body 11a includes a wireless communication circuit for exchanging signals with the contactor wafer 15 in contactless wireless communication, in addition to the above-mentioned circuits. In addition, the contactor wafer 15 includes a wireless communication circuit for exchanging signals with the tester main body 11a in contactless wireless communication. The tester main body 11a and the contactor wafer 15 conduct mutual direct wireless communication using these wireless communication circuits.

As shown in FIG. 14, contact portions 21a and a test circuit 23 are included in the contactor wafer 15 and a wireless communication circuit is included in the test circuit 23 (the contact portions 21a being not shown and lead wires 21 and the contact portions 21a being integrally shown in FIG. 14). The test circuit 23 may be formed by a process using a semiconductor manufacturing technology (semiconductor process). In addition, as can be easily understood from comparison between FIG. 14 and FIG. 1, a contact point between the contactor wafer 15 and the contactor holder 14a is not required and a wire electrically connecting the contactor wafer 15 and the tester main body 11 is also not required.

In this embodiment, the tester main body 11a acts as an inspecting apparatus main body. In this embodiment, the test head 12a and the contactor holder 14a act as a fixing mechanism.

The test head 12a may be provided either inside or outside the auto-prober 13.

Next, an electrical circuit configured to inspect a substrate by using the substrate inspecting apparatus according to this embodiment will be described with reference to FIG. 15.

As shown in FIG. 15, in the substrate inspecting apparatus 10a, an electrical circuit is configured by the tester main body 11a, the contactor wafer 15 and the wafer 16. The electrical circuit has substantially the same configuration as that of the first embodiment. The tester main body 11a includes a test generation 31 and a data processor 32. The data processor 32 includes a memory and an analog-digital/digital-analog converter (AD/DAC) in addition to a data processor. The contactor wafer 15 includes a plurality of test circuit parts 15a, as shown in a plane view of the contactor wafer 15 arranged in the upper side of a block diagram of FIG. 15. Each test circuit part 15a includes contact portions 21a and a test circuit 23. The test circuit 23 of each test circuit part 15a includes a driver 41, a comparator 42, a switch 43 and a voltage/current source 44.

In this embodiment, in addition to the above-described configuration, the tester main body 11a includes a wireless interface (I/F) and antenna 33. The test circuit 23 of each test circuit part 15a includes a wireless I/F and antenna 45. Each of the wireless I/Fs 33 and 45 includes a transmit circuit and a receive circuit. The transmit and receive circuits may be connected to the antenna via, for example, respective duplexers.

A wireless communication scheme is not particularly limited but may employ general contactless communication techniques, for example, a communication method employed in a contactless IC card used for electronic money and so on.

The contactor wafer of this embodiment has the same structure as that of the first embodiment except that the wireless communication circuit is included in the test circuit. That is, when the wireless I/F and antenna 45 are formed in the test circuit 23, the contactor wafer can be used which has the same structure as that of the first embodiment which has been described with reference to FIGS. 4 to 7. In addition, in this embodiment, alignment can be achieved by using the same aligning method as that in the substrate inspecting apparatus of the first embodiment which has been described with reference to FIGS. 8 to 10B. In addition, in this embodiment, the contactor wafer can be manufactured by using the contactor wafer manufacturing method of the first embodiment which has been described with reference to FIG. 11.

According to this embodiment, alignment between the wafer and the contactor wafer can be achieved, and the wafer and the contactor wafer may be electrically connected while the contactor wafer and the contactor holder may not be electrically connected. In addition, no wire may be provided in the contactor holder. This may result in a simplified structure of the contactor holder.

### Modification of Second Embodiment

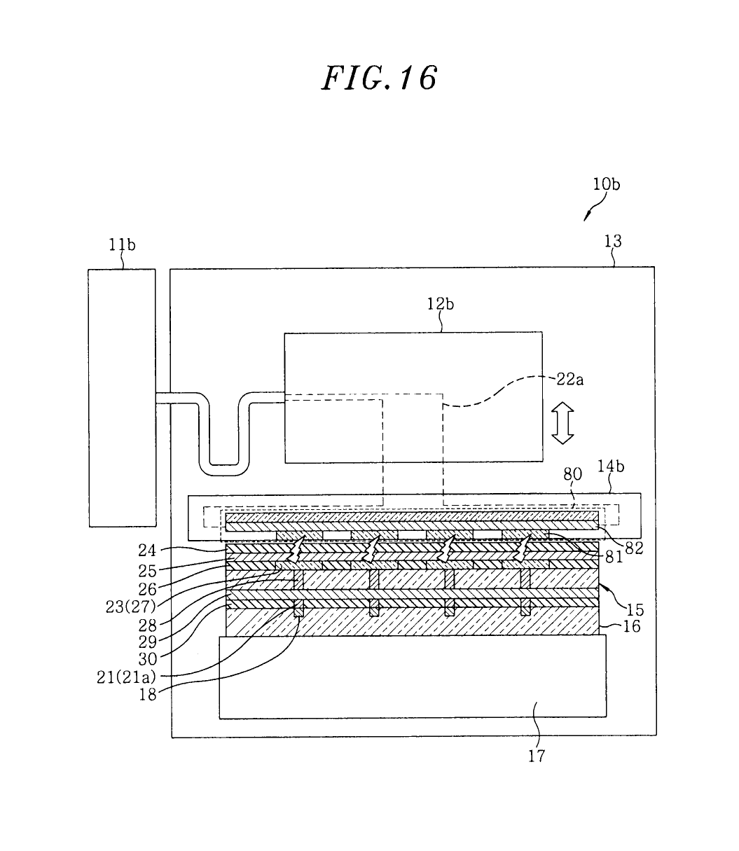

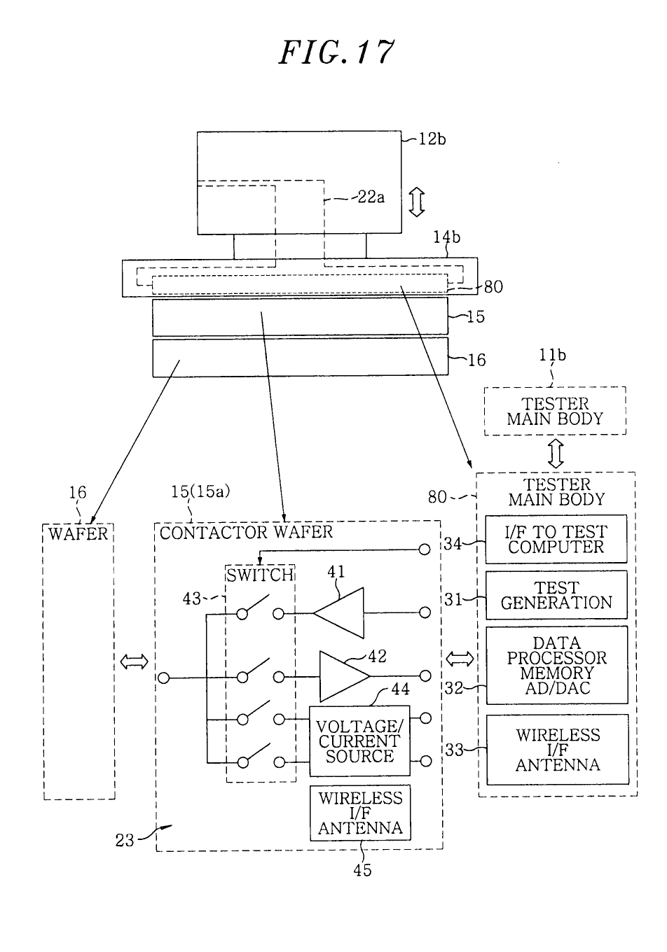

Next, a substrate inspecting apparatus and a contactor wafer according to a modification of the second embodiment will be described with reference to FIGS. 16 and 17.

As shown in FIG. 16, a substrate inspecting apparatus 10b of this modification includes a tester main body 11b, a test head 12b and an auto-prober 13. The test head 12b is vertically movably disposed within the auto-prober 13 and has a contactor holder 14b and a contactor wafer 15. The contactor holder 14b is provided below the test head 12b and holds the contactor wafer 15 by the bottom of the contactor holder 14b. The auto-prober 13 has a chuck 17 for attracting and holding the wafer 16. In addition, similar to the second embodiment, the contactor wafer 15 includes contact portions 21a and a test circuit 23 and a wireless communication circuit is included in the test circuit 23.

In this modification, a test circuit wafer 80 including a circuit 81 and a wire 82 is provided in the contactor holder 14b.

In this modification, the tester main body 11b acts as an inspecting apparatus main body. In this modification, the test head 12b and the contactor holder 14b act as a fixing mechanism.

The test head 12b may be provided either inside or outside the auto-prober 13.

Referring to FIG. 17, in the substrate inspecting apparatus 10b, an electrical circuit is configured by the tester main body 11b, the tester circuit wafer 80, the contactor wafer 15 and the wafer 16. In this modification, the contactor wafer 15 includes a driver 41, a comparator 42, a switch 43, a voltage/current source 44 and a wireless I/F and antenna 45, similarly to the second embodiment.

When the wireless I/F and antenna 45 are formed in the test circuit 23, the contactor wafer can be used which has the same structure as that of the first embodiment which has been described with reference to FIGS. 4 to 7. In addition, in this modification, alignment for the wafer 16 can be achieved by using the same aligning method as that in the substrate inspecting apparatus of the first embodiment which has been described with reference to FIGS. 8 to 10B. In addition, in this modification, the contactor wafer can be manufactured by using the contactor wafer manufacturing method of the first embodiment which has been described with reference to FIG. 11.

In this modification, the test generation 31, the data processor 32 and the wireless I/F and antenna 33, which have been provided in the test main body in the second embodiment, are provided in the tester circuit wafer 80 in the contactor holder 14b. Accordingly, a signal for inspection is generated in the tester circuit wafer 80. Wireless communication is conducted between the contactor wafer 15 (wireless I/F 45) and the tester circuit wafer 80 (wireless I/F 33). The data processor 32 includes a memory and an analog-digital/digital-analog converter (AD/DAC) in addition to a data processor. In addition, an I/F 34 to a tester computer for exchanging signals with the tester main body 11b is provided in the tester circuit wafer 80.

The wireless I/Fs 33 and 45 have substantially the same configuration as the wireless I/Fs 33 and 45 of the second embodiment and can use substantially the same communication scheme.

Even when the substrate inspecting apparatus and the contactor wafer of this modification are used, alignment between the contactor wafer 15 and the wafer 16 can be achieved with high precision. In addition, in this modification, a signal, which is generated in the test generation 31 provided in the tester circuit wafer 80 within the contactor holder 14b and processed in the data processor 32 and so on, is transmitted to the contactor wafer 15 through wireless communication and is inputted to the circuit of the wafer 16 to be inspected via the contactor wafer 15. In addition, a signal generated in the circuit under inspection of the wafer 16 is transmitted from the contactor wafer 15 to the tester circuit wafer 80 through wireless communication. This may result in reduced communication distance and wire length from the tester circuit wafer 80 to the wafer 16. A long circuit wire may greatly increase a parasitic capacitance of the circuit wire and, particularly, make it difficult to detect a high frequency signal with high precision. Accordingly, in this modification, for inspection of a semiconductor substrate having a circuit operating with a high frequency of, particularly, 1 GHz or more, it is possible to inspect the substrate with higher precision than conventional substrate inspecting apparatuses.

According to this modification, alignment between the wafer 16 and the contactor wafer 15 can be achieved, and the wafer 16 and the contactor wafer 15 may be electrically connected while the contactor wafer 15 and the contactor holder 14b may not be electrically connected via a contact point. This may result in a simplified structure of the contactor wafer 15 and the contactor holder 14b.

### Third Embodiment

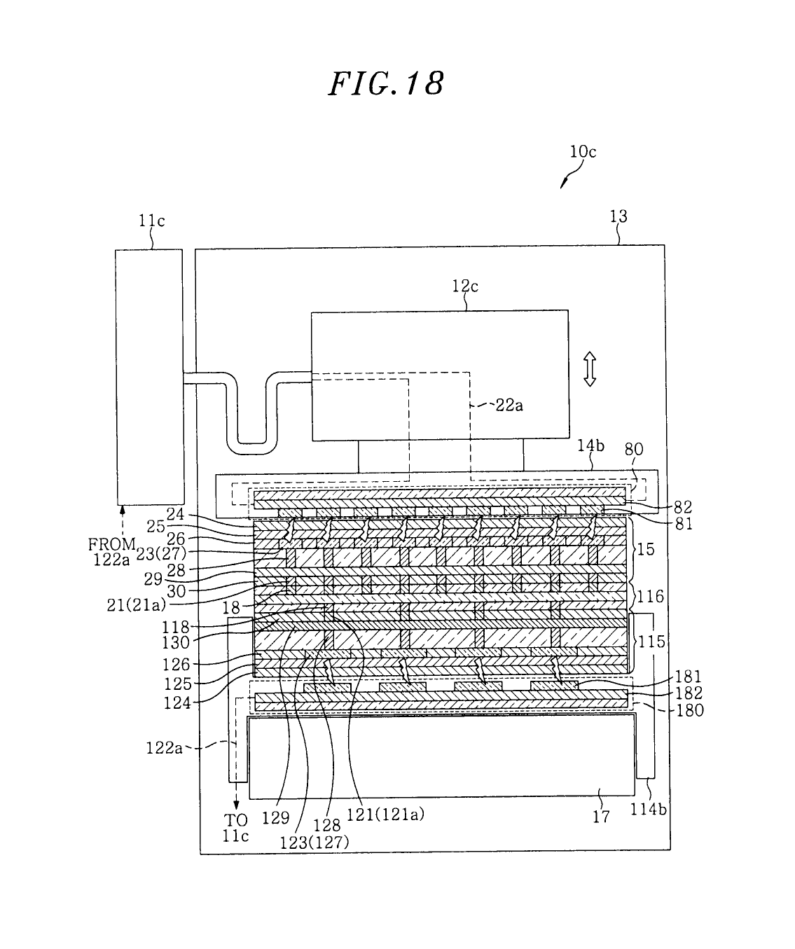

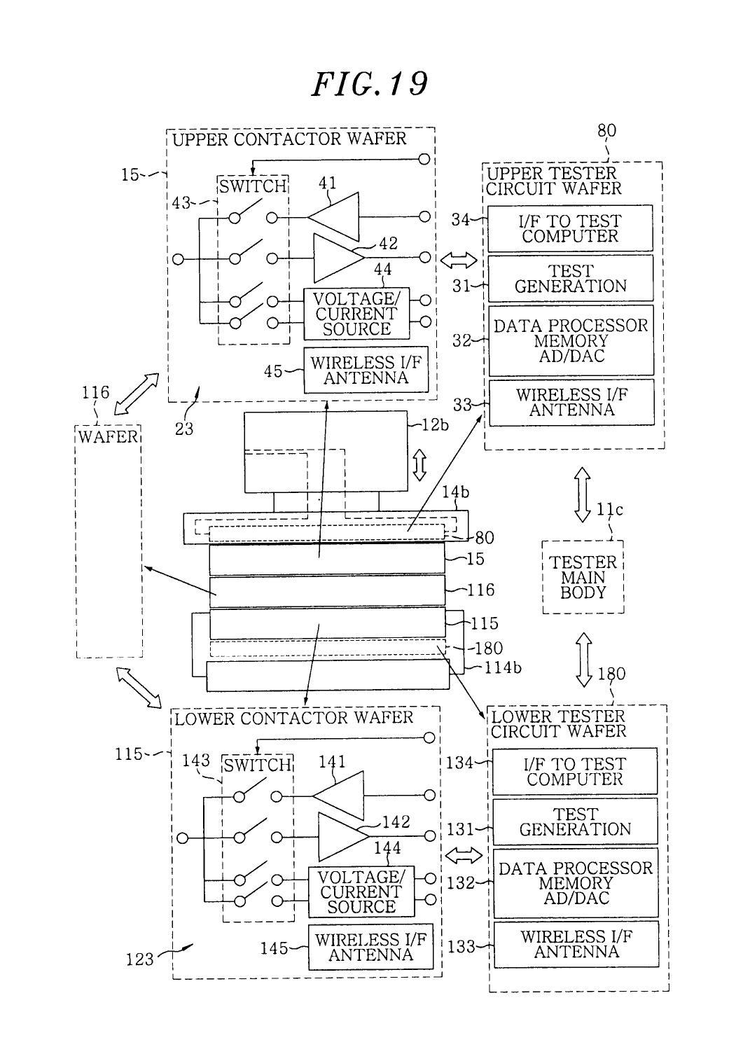

Next, a substrate inspecting apparatus and a contactor wafer according to a third embodiment will be described with reference to FIGS. 18 and 19.

FIG. 18 is a front view including a partially sectional view, which shows a substrate inspecting apparatus according to the third embodiment. As shown, a substrate inspecting apparatus 10c of this embodiment includes a tester main body 11c, a test head 12c and an auto-prober 13.

The tester main body 11c has substantially the same configuration as the tester main body 11b of the modification of the second embodiment and the auto-prober 13 has also substantially the same configuration as the auto-prober 13 of the modification of the second embodiment. In this embodiment, the test head 12c includes a contactor holder 14b, a contactor wafer 15, a lower contactor holder 114b and a lower contactor wafer 115. The contactor holder 14b has substantially the same configuration as the contactor holder 14b of the modification of the second embodiment and is attached to the lower part of the test head 12c. The contactor wafer 15 has also substantially the same configuration as the contactor wafer 15 of the modification of the second embodiment and is held by the contactor holder 14b.

As shown in FIG. 18, the lower contactor holder 114b has a concave portion in its lower part and the concave portion engages with a chuck 17. In addition, a lower tester circuit wafer 180 including a circuit 181 having a wireless communication circuit (which will be described later), a wire 182 and so on is formed in the lower contactor holder 114b. The lower contactor holder 114b is electrically connected to the tester main body 11c via the wire 182. The lower contactor wafer 115 is held in a concave portion formed in the top side of the lower contactor holder 114b. In addition, lead wires 121, contact portions 121a, a test circuit 123, an insulating layer 124, a wire 125, an insulating layer 126, a pad 127, through electrodes 128, a wire 129 and an insulating layer 130 are formed in the lower contactor wafer 115. Accordingly, the lower contactor wafer 115 can show substantially the same function as the contactor wafer 15. The test circuit 123 includes a communication circuit (which will be described later) to allow exchange of signals with the lower contactor holder 114b.

In addition, as shown in FIG. 18, a wafer 116 to be inspected is interposed between the lower contactor wafer 115 and the contactor wafer 15. This wafer 116 has electrode pads 18 in its top side and electrode pads 118 in its bottom side. The contactor portions 21a of the contact wafer 15 are electrically connected to the corresponding electrode pads 18 and the contactor portions 121a of the lower contactor wafer 115 are electrically connected to the corresponding electrode pads 118. With the above configuration, a circuit under inspection within the wafer 116 having the electrode pads 18 and 118 formed on its respective top and bottom sides can be efficiently inspected.

Next, an electrical circuit configured to inspect a substrate using the substrate inspecting apparatus according to this embodiment will be described with reference to FIG. 19. In the following description, for the sake of convenience of description, it is assumed that the contactor holder 14b is an upper contactor holder 14b, the contactor wafer 15 is an upper contactor wafer 15 and the tester circuit wafer 80 is an upper tester circuit wafer 80.

One electrical circuit is configured by the tester main body 11c, the upper tester circuit wafer 80, the upper contactor wafer 15 and the wafer 116. The upper tester circuit wafer 80 includes a test generation 31, a data processor 32, a wireless I/F and antenna 33 and an I/F 34 to a test computer, like the tester circuit wafer 80 of the modification of the second embodiment. These components are provided in a circuit within the tester circuit wafer 80 (FIG. 18). In addition, the upper contactor wafer 15 includes a driver 41, a comparator 42, a switch 43, a voltage/current source 44, a wireless I/F and antenna 45, like the modification of the second embodiment.

Another electrical circuit is configured by the tester main body 11c, the lower tester circuit wafer 180, the lower contactor wafer 115 and the wafer 116. The lower tester circuit wafer 180 also includes a test generation 131, a data processor 132, a wireless I/F and antenna 133 and an I/F 134 to the test computer, like the upper tester circuit wafer 80. The lower contactor wafer 115 includes a driver 141, a comparator 142, a switch 143, a voltage/current source 144, a wireless I/F and antenna 145, like the upper contactor wafer 15.

The upper contactor wafer 15 of this embodiment may have the various structures of the first embodiment described with reference to FIGS. 4 to 7. In addition, in this embodiment, the upper contactor wafer 15 can be manufactured by using the contactor wafer manufacturing method of the first embodiment described with reference to FIG. 11.

The lower contactor wafer 115 can also have the same structure as that of the first embodiment and can be manufactured by using the contactor wafer manufacturing method of the first embodiment.

A wire 122a led out of the tester circuit wafer 180 provided within the lower contactor holder 114b may be connected to the tester main body 11c via either a wire (not shown) or a wireless communication circuit (not shown).

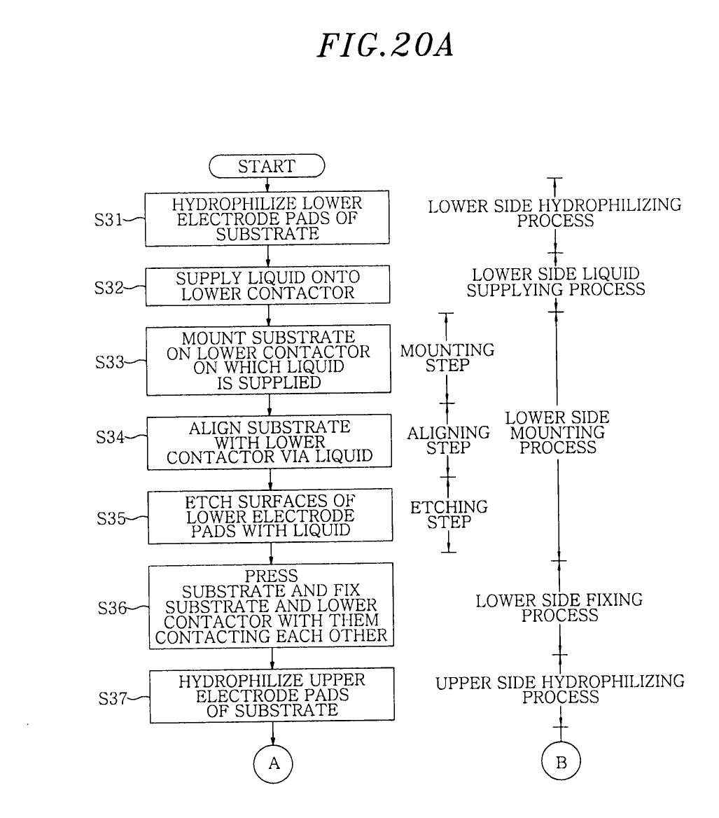

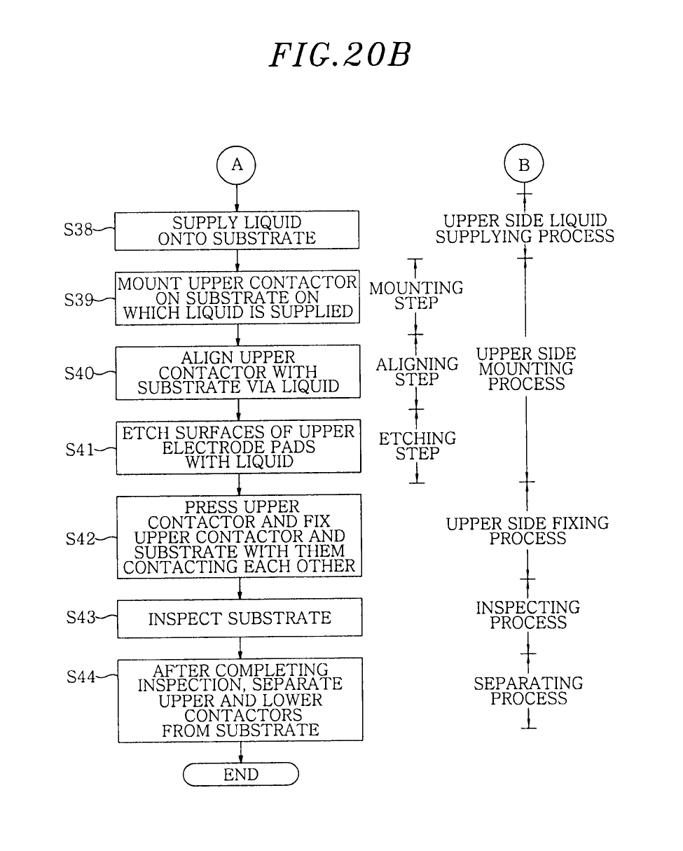

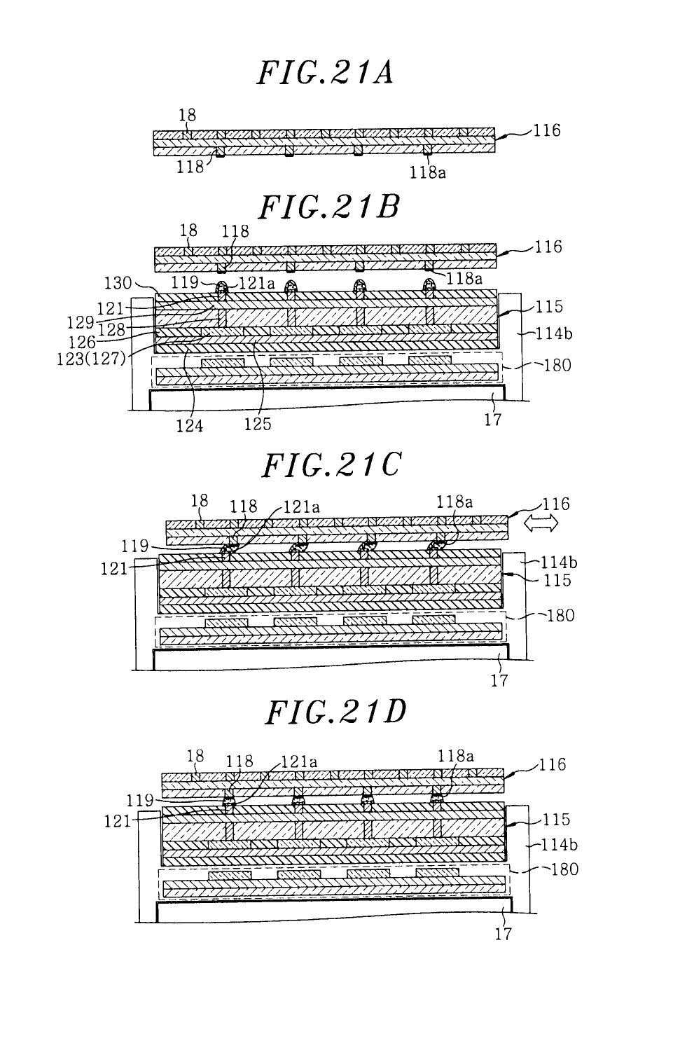

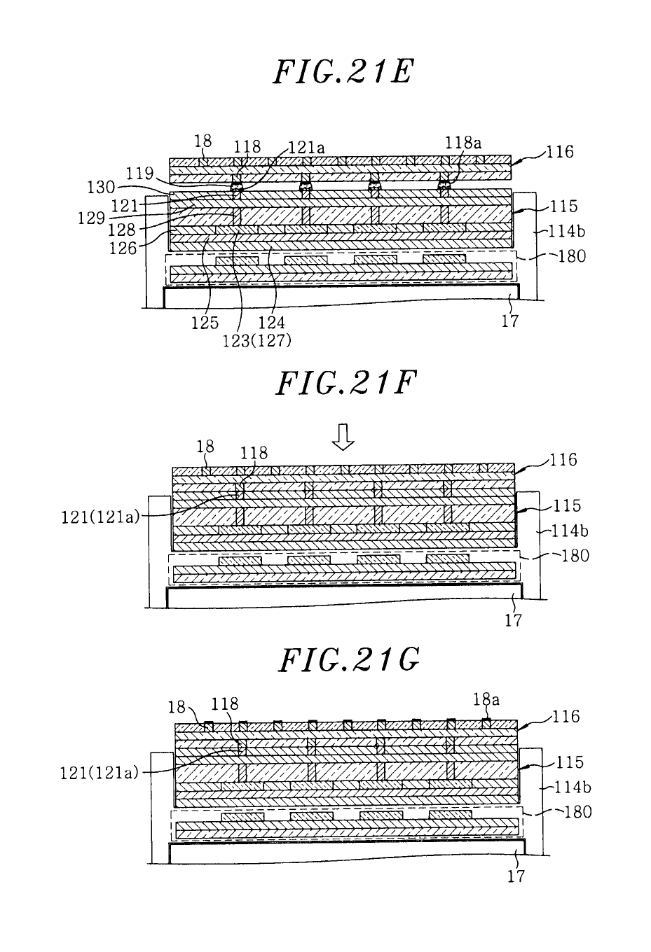

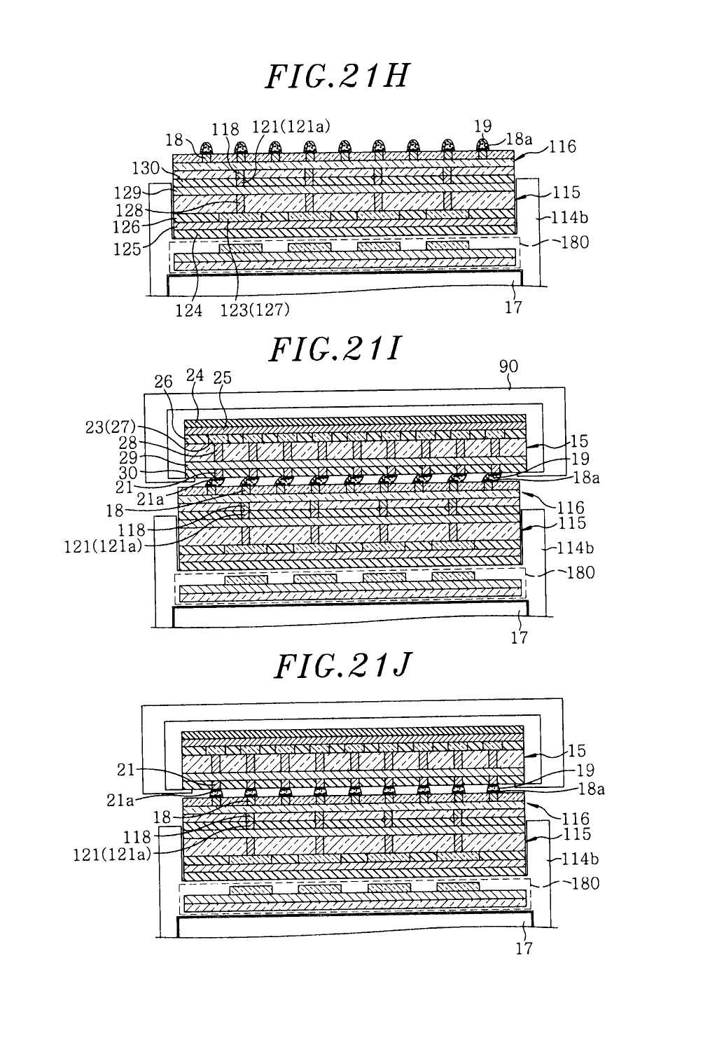

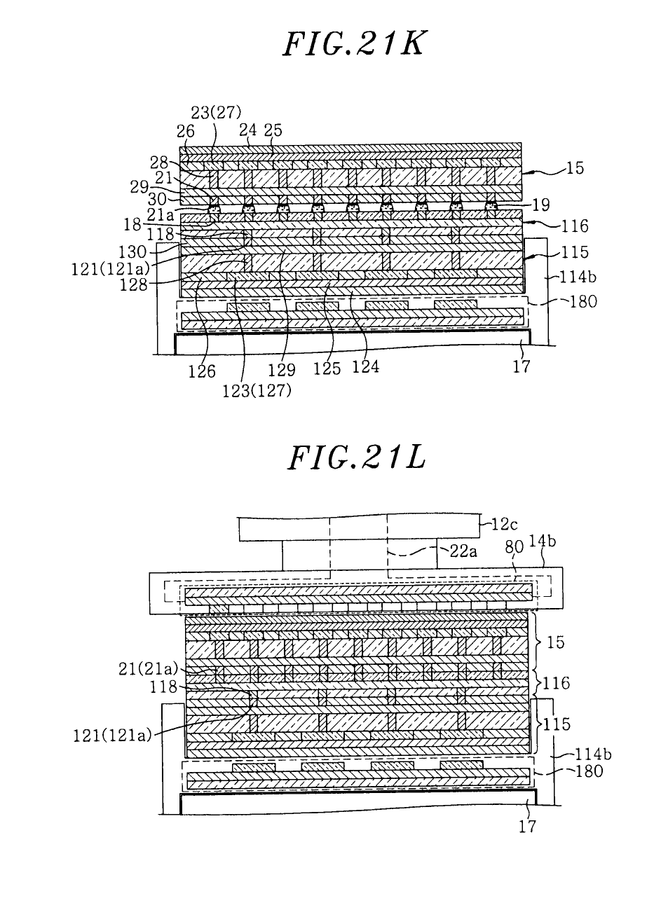

Next, an aligning method for aligning a contactor and a substrate in the substrate inspecting apparatus of this embodiment will be described with reference to FIGS. 20 to 21D.

FIGS. 20A and 20B show a flow chart for explaining processes of an aligning method in the substrate inspecting apparatus according to the third embodiment. FIGS. 21A to 21D are schematic sectional views of a contactor and a substrate in steps of an aligning method in the substrate inspecting apparatus according to the third embodiment. In addition, FIGS. 20A and 20B show an aligning method in the substrate inspecting apparatus as well as a substrate inspecting method including the aligning method.

First, a lower side hydrophilizing process is performed (S31). Specifically, a wafer 116 manufactured as a stack substrate by adhesion or the like and having electrode pads formed in both top and bottom surfaces thereof is prepared and lower electrode pads 118 formed on the bottom surface is subjected to a hydrophilizing process. In addition, in this embodiment, regions other than the lower electrode pads 118 are subjected to a hydrophobizing process. In FIGS. 21A to 21D, the surfaces of the lower electrode pads 118 subjected to the hydrophilizing process is denoted by reference numeral 118a.

The hydrophilizing process for the lower electrode pads 118 and the hydrophobizing process for the regions other than the lower electrode pads 118 may be performed as in the method described in the first embodiment. If a lower dummy electrode pad is present, the hydrophilizing process may be performed for the lower dummy electrode pad.

Next, a lower side liquid supplying process is performed (S32). Specifically, a liquid is supplied onto the lower contactor wafer 115 which is accommodated in a concave portion of the top side of the lower contactor holder 114b and has hydrophilized lower contact portions 121a formed thereon. By the supply of the liquid, liquid droplets 119 are formed on and around the lower contact portions 121a formed on the surfaces of lead electrodes 121 of the lower contactor wafer 115, as shown in FIG. 21B. See the first embodiment for a liquid supplying method, material of the liquid and a liquid applying method.

If a dummy contact portion is present in the lower contactor wafer 116, liquid is also applied on the dummy contact portion and liquid droplets are formed on the dummy contactor portion.

Next, a lower side mounting process is performed (S33 to S35). The lower side mounting process includes a mounting step (S33), an aligning step (S34) and an etching step (S35).

First, in the mounting step, as shown in FIG. 21C, the wafer 116 is mounted on the lower contactor wafer 115 in which the liquid droplets 119 are formed. That is, the wafer 116 is mounted on the lower contactor wafer 115 such that the lower contact portions 121a formed on the surfaces of the lead electrodes 121 of the lower contactor wafer 115 contact the lower electrode pads 118 via the liquid droplets 119.

In addition, although the wafer 116 is aligned with the lower contactor wafer 115 prior to the mounting step, this alignment does not require high precision. When mounted, there is no need to apply a force to the wafer 116 in any direction.

The hydrophilizing process may be performed for the lower contact portions 121a of the lower contactor wafer 115, like the lower electrode pads 118 of the wafer 116. Alternatively, the lower contact portions 121a may be formed using hydrophilic material such as metal or the like having wettability to liquid.

In addition, the wafer 116 may be mounted on the lower contactor wafer 115 by means of a transfer apparatus (not shown).

The wafer 116 mounted on the contactor wafer 115 in the mounting step S33 is self-aligned with the lower contactor wafer 115 by virtue of a surface tension of the liquid droplets 119, as shown in FIG. 21D.

If the above-mentioned lower dummy electrode pad is provided in the wafer 116 and the above-mentioned lower dummy contact portion is provided in the lower contactor wafer 115, the lower dummy electrode pad and the lower dummy contact portion are contacted with and are aligned with each other via the liquid.

After the lower contactor wafer 115 and the wafer 116 are aligned with each other in the mounting step S33, the lower contactor wafer 115 and the wafer 116 are left for a predetermined period of time, as shown in 21E. In the meantime, the surfaces of the lower electrode pads 118 of the wafer 116 and/or the lower contact portions 121a of the lower contactor wafer 115 are reduced or etched by the liquid droplets 119. That is, even when an oxide film or a film generated due to contamination is formed on the surfaces of the lower electrode pads 118 and/or the surfaces of the lower contact portions 121a, the oxide film or the generated film can be removed by the liquid droplets 119.

Accordingly, like the first embodiment, as the liquid of the liquid droplets 119, liquid having a property to reduce or etch the oxide film or the like can be used.

Next, a lower side fixing process is performed (S36). Specifically, as shown in FIG. 21F, the wafer 116 is pressed to the lower contactor wafer 115 to closely adhere the lower electrode pads 118 to the lower contact portions 121a. (In addition, in FIGS. 21F to 21L, the lower contact portion 121a is not shown and the lead wires 121 and the lower contact portions 121a are integrally shown.) In addition, since the surfaces of the lower electrode pads 118 and the surfaces of the lower contact portions 121a have been cleaned by the liquid droplets 119, there is no need to apply a horizontal force to the wafer 116.

In addition, when the lower side fixing process is omitted and an upper side fixing process (S42), which will be described later, is performed, the wafer 116 and the lower contactor wafer 115 may also be fixed.

Next, an upper side hydrophilizing process is performed (S37). Specifically, upper electrode pads 18 of the wafer 116 are subjected to a hydrophilizing process. In addition, in this embodiment, regions other than the upper electrode pads 18 are subjected to a hydrophobizing process. The hydrophilizing process and the hydrophobizing process may be performed as in the method described in the first embodiment. In FIGS. 21G to 21J, the surfaces of the upper electrode pads 18 subjected to the hydrophilizing process are denoted by reference numeral 18a.

Next, an upper side liquid supplying process is performed (S38). Specifically, a liquid is supplied onto the wafer 116 as in the method described in the first embodiment. By the supply of the liquid, liquid droplets 19 are formed on and around the surfaces 18a, as shown in FIG. 21H.

Next, an upper side mounting process is performed (S39 to S41). The upper mounting process includes a mounting step (S39), an aligning step (S40) and an etching step (S41).

First, in the mounting step, as shown in FIG. 211, the upper contactor wafer 15 is transferred and mounted on the wafer 116 having the liquid droplets 19 formed thereon by means of a wafer transfer arm 90. At this time, there is no need to perform alignment with high precision by the wafer transfer arm 90. When mounted, there is also no need to apply a transverse (horizontal) force to the wafer 116.

The hydrophilizing process may be performed for the upper contact portions 21a of the upper contactor wafer 15, like the upper electrode pads 18 of the wafer 116. Alternatively, the upper contact portions 21a may be formed using hydrophilic material such as metal or the like having wettability to liquid.

The upper contactor wafer 15 mounted on the wafer 116 is self-aligned with the wafer 116 in S40 by virtue of a surface tension of the liquid droplets 19, as shown in FIG. 21J.

If the above-mentioned upper dummy electrode pad is provided in the wafer 116 and the above-mentioned upper dummy contact portion is provided in the upper contactor wafer 15, the upper dummy electrode pad and the upper dummy contact portion are contacted with and are aligned with each other via the liquid.

After the lower contactor wafer 115 and the wafer 116 are aligned with each other in the mounting step S40, the upper contactor wafer 15 is left for a predetermined period of time, as shown in 21K. In the meantime, the surfaces of the upper electrode pads 18 of the wafer 116 and/or the surfaces of the upper contact portions 21a of the upper contactor wafer 15 are reduced or etched by the liquid droplets 119. That is, even when an oxide film or a film generated due to contamination is formed on the surfaces of the upper electrode pads 18 and/or the surfaces of the upper contact portions 21a, the oxide film or the generated film can be removed by the liquid droplets 119.

Next, an upper side fixing process is performed (S42). Specifically, as shown in FIG. 21L, the contactor wafer 15 is pushed down by descending the contactor holder 14b and the contactor wafer 15 and the wafer 116 are fixed with them contacting each other, as in the method described in the first embodiment. (In addition, in FIG. 21L, the lower contact portion 121a is not shown.)

After the aligning method (S31 to S42) is performed in the substrate inspecting apparatus, substantially the same inspecting process as the inspecting process (S17 in FIG. 8) described in the first embodiment is performed (S43). However, the inspecting process in this embodiment is also performed for the bottom side of the wafer 116. Specifically, a signal is sent through wireless communication from the tester main body 11c to the lower contactor wafer 115 via the lower tester circuit wafer 180 within the lower contactor holder 114b, and, based on the sent signal, a signal is generated by controlling the switch and the driver of the test circuit 123 provided in the lower contactor wafer 115 and is inputted to a lower input of the circuit under inspection of the wafer 116. As a result, a signal generated from the lower output of the circuit under inspection of the wafer 116 is read by controlling the switch and the comparator of the test circuit 123 of the lower contactor wafer 115 and is sent through wireless communication from the lower contactor wafer 115 to the lower tester circuit wafer 180 and the tester main body 11c.

After the inspecting process, a separating process is performed (S44). The separating process may be performed as in the separating process (S18) of the first embodiment.

According to the substrate inspecting apparatus and the contactor wafer of this embodiment, alignment between the wafer 116 having the electrode pads in its top and bottom sides, the contactor wafer 15 and the contactor wafer 115 can be achieved with high precision. In addition, in this embodiment, it is possible to reduce wire length from the wafer 116 to a signal reading circuit and inspect a semiconductor substrate having a circuit operating with a high frequency of, particularly, 1 GHz or more, with higher precision than conventional substrate inspecting apparatuses.

### Fourth Embodiment

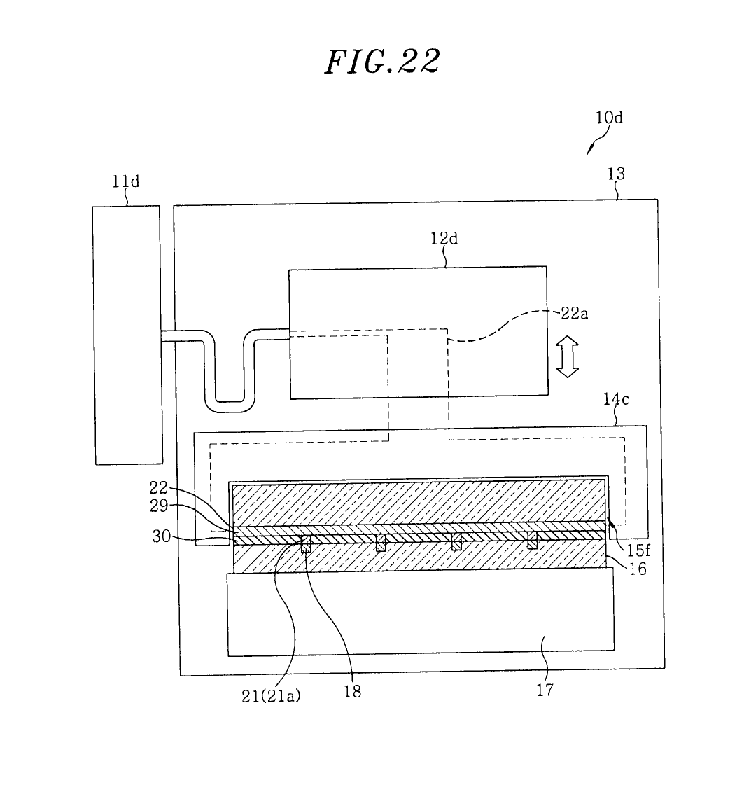

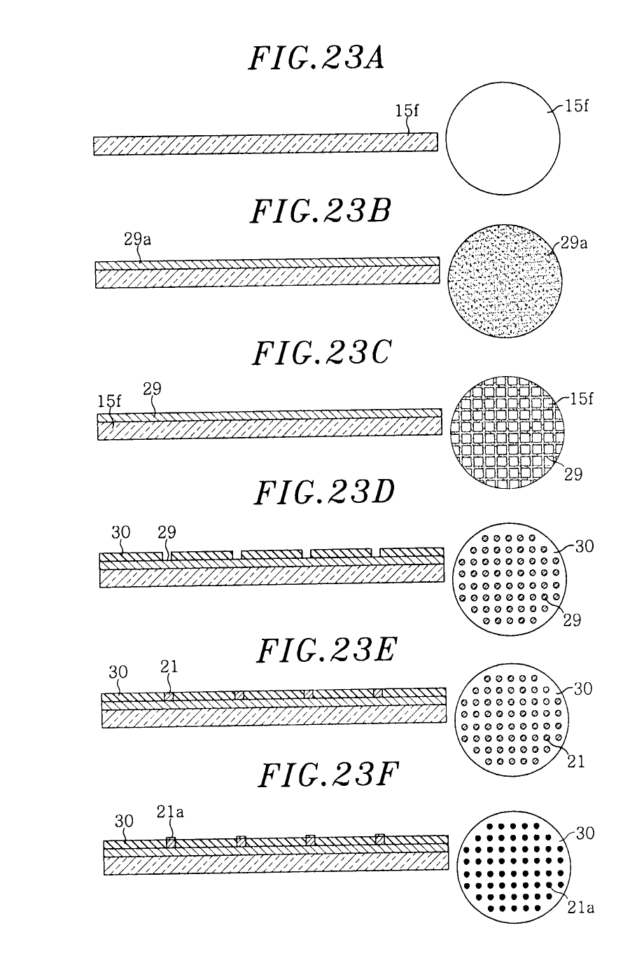

Next, a substrate inspecting apparatus, a contactor wafer and a contactor wafer manufacturing method according to a fourth embodiment will be described with reference to FIGS. 22 and 23.

First, a substrate inspecting apparatus of this embodiment will be described with reference to FIG. 22. FIG. 22 is a front view including a partially sectional view, which shows a substrate inspecting apparatus according to this embodiment. As shown, a substrate inspecting apparatus 10d of this embodiment includes a tester main body lid, a test head 12d and an auto-prober 13. The auto-prober 13 has substantially the same configuration as the auto-prober 13 of the first embodiment.

The test head 12d has a contactor holder 14c and a contactor wafer 15f. The contactor holder 14c and a contactor wafer 15f are electrically connected with each other via contact points 22 provided in the contactor wafer 15f. In addition, contact portions 21a contacting electrode pads 18 of a wafer 16 to be inspected are provided in the contactor wafer 15f.

In this embodiment, test circuits such as a driver, a comparator, a switch, a voltage/current source and so on are not provided in the contactor wafer 15f. Instead, a test circuit may be provided in the tester main body 11d or a tester circuit wafer including a test circuit may be provided within the contactor holder 14c.

In this embodiment, alignment can be performed by using the aligning method in the substrate inspecting apparatus described in the first embodiment with reference to FIGS. 8 to 10.

Next, a method for manufacturing a contactor wafer according to this embodiment will be described with reference to FIG. 23. FIG. 23 is schematic sectional (in left) and plan (in right) views showing a contactor wafer in steps of a method for manufacturing the contactor wafer according to this embodiment.

As shown in FIG. 23A, a wafer 15f is first prepared. As described above, in this embodiment, no test circuit is formed in the wafer 15f. Next, as shown in FIG. 233, a metal film 29a for forming a wire 29 is formed on the wafer 15f.

Subsequently, a mask is formed on the metal film 29a and the wire 29 is formed by etching the metal film 29a exposed through the mask, as shown in 23C. The etching used may be either wet etching or dry etching.

Next, an insulating layer 30 is formed on the entire surface of the wafer 15f on which the wire 29 is formed, and openings are formed in the insulating layer 30 by photolithography and etching, as shown in FIG. 23D. The wire 29 is exposed in the openings. Alternatively, a mask may be formed at a position at which the openings are to be formed, the insulating layer 30 may be formed to cover the mask, the wire 29 and the top surface of the wafer 15f, and the openings may be formed in the insulating layer 30 by lifting off the mask. The insulating layer 30 may be formed by using any methods including CVD, PVD, application, deposition and the like as long as they do not damage the wire previously formed. The insulating layer 30 may be made of any resin material such as polyimide in addition to a silicon oxide.

Next, by filling the openings of the insulating layer 30 with metal by using a plating or the like, lead wires 21 to be electrically connected with the wire 29 are formed as shown in FIG. 23E.

Next, contact portions 21a are formed on the lead wires 21 led on the top, as shown in FIG. 23F. The contact portions 21a are preferably made of hydrophilic metal. The contact portions 21a may have either a planar shape flush with the top of the insulating layer 30 or a convex shape projecting from the top of the insulating layer 30. Alternatively, the contact portions 21a may have a concave shape lower than the surface of the insulating layer 30. In this case, the contact portions 21a may be electrically connected with the electrode pads 18 (FIG. 22) of the wafer 16 to be inspected via conductive liquid. A contactor wafer 15 is manufactured by the above-described manufacturing method.

Alternatively, without forming the contact portions 21a, the lead wires 21 may be used instead of the contact portions 21a. In this case, the lead wires 21 may be formed to project from the top of the insulating layer 30.

In addition, after forming the contact portions 21a (or forming the lead wires 21 if the contact portion is not formed), the contact portions 21a (or the lead wires 21) may be subjected to a hydrophilizing process by applying a photocatalyst on the surfaces and then selectively irradiating the surfaces with a UV ray via a mask. Regions other than the contact portions 21a (or the lead wires 21) may be subjected to a hydrophobizing process. The hydrophobizing process may be performed by selectively applying hydrophobic material such as an organic silicon compound. A contactor wafer is manufactured by the above-described manufacturing method.

Even according to this embodiment, it is possible to achieve self-alignment and electrical connection between a wafer to be inspected and a contactor wafer easily.

While the invention has been shown and described with respect to the embodiments, it will be understood by those skilled in the art that various changes and modification may be made without departing from the scope of the invention as defined in the following claims.

This international application is based upon and claims the benefit of priority to Japan Patent Application No. 2009-211003, filed on Sep. 11, 2009, the entire contents of which are incorporated herein by reference.

What is claimed is:

1. A substrate inspecting apparatus comprising:
an inspecting apparatus main body for electrically inspecting a substrate on which an electronic circuit and electrode pads are formed; and
a first contactor which includes contact portions made of conductive material and is electrically connected to the inspecting apparatus main body,
wherein the contact portions are electrically connected to the electrode pads of the substrate via conductive liquid.

2. The substrate inspecting apparatus of claim 1, wherein the electrode pads have hydrophilicity, and
wherein the first contactor is aligned with the substrate as the contact portions are mounded on the substrate on a surface of which liquid is supplied.

3. The substrate inspecting apparatus of claim 1, wherein the liquid has a property to etch an oxide film of the contact portions and/or the electrode pads.

4. The substrate inspecting apparatus of claim 1, wherein the contact portions have hydrophilicity.

5. The substrate inspecting apparatus of claim 1, further comprising a fixing mechanism to press and fix the first contactor aligned with the substrate to the substrate.

6. The substrate inspecting apparatus of claim 5, wherein the first contactor has contact points to be electrically connected to the fixing mechanism,
wherein the fixing mechanism is electrically connected to the inspecting apparatus main body, and
wherein a signal is exchanged between the first contactor and the inspecting apparatus main body via the contact points and the fixing mechanism.

7. The substrate inspecting apparatus of claim 1, wherein the first contactor has a wireless communication circuit, and
wherein a signal is exchanged between the first contactor and the inspecting apparatus main body via the wireless communication circuit.

8. The substrate inspecting apparatus of claim 1, wherein a dummy contact portion is formed in the first contactor, and
wherein the dummy contact portion has hydrophilicity.

9. The substrate inspecting apparatus of claim 1, wherein a circuit including a driver, a comparator and a switch is provided in the first contactor.

10. The substrate inspecting apparatus of claim 1, wherein surfaces of the contact portions of the first contactor are coated with insulating material.

11. The substrate inspecting apparatus of claim 10, wherein the insulating material is a resist.

12. The substrate inspecting apparatus of claim 11, wherein the resist is applied by using an inkjet printing method.

13. The substrate inspecting apparatus of claim 1, wherein the first contactor has a contact portion which is not electrically connected.

14. The substrate inspecting apparatus of claim 1, further comprising a second contactor which includes contact portions made of conductive material and is electrically connected to the inspecting apparatus main body,
wherein the contact portions of the first contactor are electrically connected to electrode pads formed on the top of the substrate via conductive liquid, and
wherein the contact portions of the second contactor are electrically connected to electrode pads formed on the bottom of the substrate via conductive liquid.

15. An aligning method, in a substrate inspecting apparatus for electrically inspecting a substrate on which an electronic circuit and electrode pads are formed, for aligning a first contactor with the substrate, the contactor electrically connecting the substrate and an inspecting apparatus main body of the substrate inspecting apparatus, the aligning method comprising:
a first hydrophilizing step of hydrophilizing electrode pads formed on the top of the substrate;
a first liquid supplying step of supplying liquid onto the substrate;
a first mounting step of mounting the first contactor on the substrate on which the liquid is supplied; and
an aligning step of aligning the first contactor with the substrate via the liquid.

16. The aligning method of claim 15, wherein the liquid has electric conductivity.

17. The aligning method of claim 15, wherein the liquid has a property to etch an oxide film on contact portions of the first contactor and/or the electrode pads.

18. The aligning method of claim 15, wherein contact portions which are provided in the first contactor and are electrically connected to the electrode pads has hydrophilicity.

19. The aligning method of claim 15, further comprising:
a second hydrophilizing step of hydrophilizing electrode pads formed on the bottom of the substrate;
a second liquid supplying step of supplying liquid onto contact portions of a second contactor electrically connecting the substrate to the inspecting apparatus main body;
a second mounting step of mounting the substrate on the second contactor on which the liquid is supplied; and
an aligning step of aligning the second contactor with the substrate via the liquid.
